(19) United States
(12) Patent Application Publication
(10) Pub. No.: US 2017/0162808 A1
(43) Pub. Date: Jun. 8, 2017

(54) PHOTOELECTRIC CONVERSION DEVICE

(71) Applicant: SUMITOMO CHEMICAL COMPANY, LIMITED, Tokyo (JP)

(72) Inventor: Yasunori UETANI, Tsukuba-shi (JP)

(73) Assignee: SUMITOMO CHEMICAL COMPANY, LIMITED, Tokyo (JP)

(21) Appl. No.: 15/325,815

(22) PCT Filed: Jun. 30, 2015
(86) PCT No.: PCT/JP2015/068756

§ 371 Date: Jan. 12, 2017

(30) Foreign Application Priority Data
Jul. 14, 2014 (JP) 2014-143986

(51) Int. Cl. H01L 51/42; H01L 51/00; C08G 61/12; H01L 27/30; H01L 51/44

(52) U.S. Cl. CPC H01L 51/4246; H01L 27/302; H01L 51/442; H01L 51/448; C08G 61/126; H01L 51/0043; H01L 51/0036; H01L 51/0035; C08G 2261/91; C08G 2261/3246; C08G 2261/3247; C08G 2261/124; C08G 2261/228; C08G 2261/1412; C08G 2261/3243

(57) ABSTRACT

A photoelectric conversion device comprising a layer A having a hue value of h₁ in the L*C*h color system calculated from the transmittance spectrum and a layer B having a hue value of h₂ in the L*C*h color system calculated from the transmittance spectrum, wherein the above-described h₁ and the above-described h₂ satisfy h₁+100≦h₂≦h₁+260.

### TECHNICAL FIELD

The present invention relates to a photoelectric conversion device.

### BACKGROUND ART

A variety of uses such as placing on windows and the like of a transparent or semi-transparent photoelectric conversion device are expected since the device can generate electricity while allowing transmission of light.

For example, Non-patent document 1 discloses a transparent or semi-transparent photoelectric conversion device having a plurality of transparent electrodes and a plurality of organic layers.

### PRIOR ART DOCUMENT

### Non-Patent Document

Non-patent document 1: Energy & Environmental Science, 2013, No. 6, pp. 2714-2720

### SUMMARY OF THE INVENTION

When used on windows, it is desirable that the chromaticness indicating vividness of color of a photoelectric conversion device is low. The above-described photoelectric conversion device disclosed in Non-patent document 1 shows coloration and has high chromaticness.

An object of the present invention is to provide a photoelectric conversion device having low chromaticness as a whole.

The present invention is as described below.

[1] A photoelectric conversion device comprising a layer A having a hue value of h₁ in the L*C*h color system calculated from the transmittance spectrum and a layer B having a hue value of h₂ in the L*C*h color system calculated from the transmittance spectrum, wherein h₁ and h₂ satisfy h₁+100≦h₂≦h₁+260.

[2] The photoelectric conversion device according to [1], wherein the device is an organic photoelectric conversion device.

[3] The photoelectric conversion device according to [1] or [2], wherein the chromaticness C* in the L*C*h color system calculated from the transmittance spectrum is 12 or less.

[4] The photoelectric conversion device according to any one of [1] to [3], wherein at least one of the layer A and the layer B is a semiconductor layer.

[5] The photoelectric conversion device according to [4], wherein both the layer A and the layer B are semiconductor layers.

[6] The photoelectric conversion device according to [4] or [5], wherein the semiconductor layer is an active layer.

[7] The photoelectric conversion device according to any one of [1] and [4] or [6], wherein either the layer A or the layer B is a toning layer.

[8] The photoelectric conversion device according to any one of [1] to [7], wherein at least one of the layer A and the layer B has a chromaticness C* of 12 or more in the L*C*h color system calculated from the transmittance spectrum of the each layer only.

[9] The photoelectric conversion device according to any one of [1] to [7], wherein both the layer A and the layer B have a chromaticness C* of 12 or more in the L*C*h color system calculated from the transmittance spectrum of the each layer only.

### BRIEF EXPLANATION OF DRAWINGS

FIG. 1 is a view showing the transmittance spectra of organic photoelectric conversion devices used in Examples 1 to 3 and Comparative Examples 1 and 2, respectively.

FIG. 2 is a view showing the transmittance spectra of a first active layer only and a second active layer only.

### MODES FOR CARRYING OUT THE INVENTION

The present invention will be illustrated in detail below.

The photoelectric conversion device of the present invention is a photoelectric conversion device comprising a layer A having a hue value of h₁ in the L*C*h color system calculated from the transmittance spectrum and a layer B having a hue value of h₂ in the L*C*h color system calculated from the transmittance spectrum, wherein h₁ and h₂ satisfy h₁+100≦h₂≦h₁+260 (condition 1).

It is preferable that h₁+110≦h₂≦h₁+250 (condition 1-1), it is more preferable that h₁+120≦h₂≦h₁+240 (condition 1-2), from the standpoint of more decreasing the chromaticness of the photoelectric conversion device of the present invention.

Under this condition, the hue value h (h₁) in the L*C*h color system of the layer A is lower than the hue value h (h₂) of the layer. Further, h₁ and h₂ satisfy 0≦h₁, h₂≦360.

The photoelectric conversion device of the present invention has low chromaticness as a whole, by lamination of the two layers A and B which are in a relation of mutually complementary colors, that is, the two layers A and B satisfying (condition 1), preferably (condition 1-1), more preferably (condition 1-2).

Each of the layer A and the layer B is a layer constituting a photoelectric conversion device. The layer A and the layer B include an electrode as an electrically conductive layer; a semiconductor layer disposed between electrodes; a sealing layer; a supporting substrate; a protective layer; a toning layer, and the like. The semiconductor layer may be constituted of any of an organic compound and an inorganic compound and may also be a mixture of them. The semiconductor layer includes an active layer; and a charge transporting layer selected from a hole transporting layer and an electron transporting layer. It is preferable that one of the layer A and the layer B is a semiconductor layer, it is more preferable that one is a semiconductor layer and the other is a semiconductor layer or a toning layer, it is further preferable that both of them are semiconductor layers. It is preferable that one or both of the above-described semiconductor layers are active layers.

The structure of laminating the layer A and the layer B may be a multi-junction structure in which the layer A and the layer B (for example, two semiconductor layers) are laminated between electrodes, or may be a structure in which two photoelectric conversion devices each having the layer A and the layer B are simply superimposed and wiring is installed.

In the photoelectric conversion device of the present invention, all layers and electrodes constituting the device show light permeability. In the present specification, “showing light permeability” denotes “transparent or semi-transparent”. Hereinafter, “showing light permeability” is described simply as “transparent” including transparent and semi-transparent, in some cases.

As the photoelectric conversion device of the present invention, an organic photoelectric conversion device using an organic material as a semiconductor layer is especially preferable since it is thin and lightweight.

The chromaticness C* in the L*C*h color system can be calculated according to the equality: C*=√(a*̂2+b*̂2) using a* and b* determined by calculating the L*a*b* chromaticity coordinate in the L*a*b* color system from the transmittance spectrum. The hue h (value) in the L*C*h color system can be calculated according to the equality: h=arctan(b*/a*) using a* and b* determined by calculating from the transmittance spectrum. Colors situated at mutually opposite hue angles are in a relation of complementary colors. Regarding, for example, specific colors, “red/blue-green”, “red-purple/green” and “yellow/blue-purple” are in a relation of mutually complementary colors.

For use on windows, it is preferable that the chromaticness of a photoelectric conversion device is lower. Low chromaticness as a whole in the photoelectric conversion device of the present invention denotes usually that the chromaticness C* in the L*C*h color system calculated from the transmittance spectrum of a photoelectric conversion device is 12 or less. The chromaticness C* is more preferably 10 or less, further preferably 8 or less.

For decreasing the chromaticness as a whole of the photoelectric conversion device of the present invention, all layers (including electrodes) other than the layer A and the layer B of the photoelectric conversion device of the present invention have a visible light transmission of preferably 70% or more, more preferably 80% or more. This visible light transmission is visible light transmission defined as an optical performance evaluation item of JIS A5759.

For decreasing the chromaticness as a whole of the photoelectric conversion device of the present invention, it is preferable that all layers (including electrodes) other than the layer A and the layer B of the photoelectric conversion device of the present invention have chromaticness lower than the chromaticness of any of the layer A and the layer B.

In the present invention, chromaticness C* and hue h in the L*C*h color system of a photoelectric conversion device can be determined by measuring the transmittance spectrum in the lamination direction of a photoelectric conversion device by a spectrophotometer and calculating the L*a*b* chromaticity coordinate from the transmittance spectrum in the range of 380 nm to 780 nm. In a similar fashion, also chromaticness C* and hue h in the L*C*h color system of the layer A or the layer B can be determined by measuring the transmittance spectrum in the thickness direction of the layer A only or the transmittance spectrum in the thickness direction of the layer B only by a spectrophotometer and calculating the L*a*b* chromaticity coordinate from the transmittance spectrum in the range of 380 nm to 780 nm.

The photoelectric conversion device of the present invention is endowed with low chromaticness as a whole by having the layer A and the layer B satisfying (condition 1), preferably (condition 1-1), more preferably (condition 1-2). Each of the layer A and the layer B shows coloration and may have high chromaticness. For example, an active layer showing coloration and having relatively high chromaticness though manifesting high efficiency can be used as the layer A and/or the layer B. That is, the photoelectric conversion device of the present invention can be suitably used even if either the chromaticness C* in the L*C*h color system of the layer A only or the chromaticness C* in the L*C*h color system of the layer B only is 12 or more, and can be suitably used even if both of them are 12 or more.

The organic photoelectric conversion device which is one embodiment of the photoelectric conversion device of the present invention will be illustrated specifically.

### <1> Constitution of Organic Photoelectric Conversion Device

The organic photoelectric conversion device of the present invention is a photoelectric conversion device having an anode and a cathode and containing one or more semiconductor layers between the anode and the cathode.

The semiconductor layer includes an active layer; an intermediate layer; a charge transporting layer selected from a hole transporting layer and an electron transporting layer; and the like. The organic photoelectric conversion device of the present invention may contain a sealing layer, a supporting substrate, a protective layer, a toning layer and the like. All layers (including electrodes) constituting the organic photoelectric conversion device of the present invention show light permeability.

One embodiment of the organic photoelectric conversion device of the present invention is an organic photoelectric conversion device having a constitution in which an anode and a cathode are carried on a supporting substrate, a semiconductor layer is laminated between the anode and the cathode and the device is sealed with a sealing layer.

The organic photoelectric conversion device of the present invention contains the layer A and the layer B satisfying (condition 1), preferably (condition 1-1), more preferably (condition 1-2).

The layer A and the layer B each may be any layer constituting an organic photoelectric conversion device, and include an electrode (anode and cathode) as an electrically conductive layer, or a semiconductor layer disposed between electrodes, a sealing layer, a supporting substrate, a protective layer, a toning layer and the like. It is preferable that one of the layer A and the layer B is a semiconductor layer, it is more preferable that one is a semiconductor layer and the other is a semiconductor layer or a toning layer, it is further preferable that both of them are semiconductor layers. Moreover, it is preferable that one or both of the above-described semiconductor layers are active layers.

One preferable embodiment of the organic photoelectric conversion device of the present invention is an organic photoelectric conversion device containing a structure having two semiconductor layers between transparent electrodes, in which one of the two semiconductor layers is the layer A and the other is the layer B. It is preferable that any one of the semiconductor layers is an active layer, it is more preferable that both of them are active layers.

Another preferable embodiment of the organic photoelectric conversion device of the present invention is an organic photoelectric conversion device containing a structure having a toning layer and a semiconductor layer between transparent electrodes, in which one of the toning layer and the semiconductor layer is the layer A and the other is the layer B. It is more preferable that the semiconductor layer is an active layer.

Both an anode and a cathode are constituted of a transparent or semi-transparent electrode (transparent electrode). Incident light from the transparent or semi-transparent electrode is absorbed by an electron accepting compound and/or an electron donating compound described later in an active layer, thereby generating an exciton composed of an electron and a hole bonded. When this exciton travels in the active layer and reaches the hetero junction interface where the electron accepting compound and the electron donating compound are adjacent, electrons and holes separate due to differences of respective HOMO energies and LUMO energies at the interface and independently movable charges (electrons and holes) are generated. The generated charges move to respective electrodes and are taken out outside as electric energy (electric current).

### (Supporting Substrate)

The organic photoelectric conversion device of the present invention usually contains a supporting substrate. As the supporting substrate, one which does not change chemically in fabricating an organic photoelectric conversion device is suitably used. In the present invention, the supporting substrate includes transparent substrates such as, for example, a glass substrate, a plastic substrate, a polymer film and the like, because of necessity of transparency.

### (Electrode (Transparent Electrode))

As the anode or cathode (transparent anode or transparent cathode), transparent or semi-transparent electrically conductive metal oxide films, metal films, electrically conductive films containing an organic substance, and the like, are used. Specifically, use is made of films of indium oxide, zinc oxide, tin oxide, indium tin oxide (Indium Tin Oxide: abbreviated as ITO), indium zinc oxide (Indium Zinc Oxide: abbreviated as IZO), gold, platinum, silver, copper, aluminum, polyaniline and derivatives thereof, polythiophene and derivatives thereof, and the like. Of them, films of ITO, IZO and tin oxide are suitably used as the transparent electrode. For example, a transparent or semi-transparent electrode in which the thickness of a film constituting the above-described transparent electrode is so adjusted as to allow permeation of light is used as the transparent electrode.

The transparent or semi-transparent electrode may be formed by an application method using an emulsion (emulsified liquid) or a suspension (suspended liquid) containing nanoparticles of an electrically conductive substance, nanowires of an electrically conductive substance or nanotubes of an electrically conductive substance, dispersion liquids such as a metal paste and the like, a low melting metal in molten state and the like. The electrically conductive substance includes metals such as gold, silver and the like, oxides such as ITO (indium tin oxide) and the like, carbon nanotubes, and the like. The electrode may be constituted singly of nanoparticles or nanofibers of an electrically conductive substance, however, the electrode may also have a constitution in which nanoparticles or nanofibers of an electrically conductive substance are dispersed and placed in a given medium such as an electrically conductive polymer and the like, as disclosed in Japanese Patent Application National Publication No. 2010-525526.

The transparent electrode can take the form of a single layer or the form of a laminate of a plurality of layers.

### (Sealing Layer)

The sealing layer is provided on the side opposite to the supporting substrate side of an electrode not in contact with the supporting substrate, and blocks the semiconductor layer and the electrode from external air. As the sealing layer, one which does not change chemically in fabricating an organic photoelectric conversion device is suitably used. In the present invention, transparent sealing layers such as, for example, a glass plate, a plastic plate, a polymer film and the like are used as the sealing layer, because of necessity of transparency.

### (Protective Layer)

The protective layer (namely, passivation layer) is a layer having a function of mechanically or chemically protecting a semiconductor layer and an electrode. The protective layer is provided, for example, in contact with an electrode not in contact with a supporting substrate, between the electrode and a sealing layer. In the present invention, the protective layer includes, for example, transparent insulating inorganic films of SiO₂, Al₂O₃ and the like; transparent insulating polymer films, because of necessity of transparency and electric insulation.

### (Toning Layer)

The organic photoelectric conversion device of the present invention may have a colored semi-transparent toning layer having a relation of mutually complementary colors with some other layer, for adjustment to lower the chromaticness of an organic photoelectric conversion device. The toning layer is provided, usually, on a sealing layer or the surface of a supporting substrate. The toning layer includes, for example, a film formed by applying a material constituting a toning layer directly on a sealing layer or a supporting substrate, a glass plate toned by applying a toning material and the like, a colored semi-transparent film, and the like.

### (Active Layer)

The active layer can take the form of a single layer or the form of a laminate of a plurality of layers. The active layer having a constitution of a single layer is constituted of a layer containing an electron accepting compound and an electron donating compound.

The active layer having a constitution of a laminate of a plurality of layers is constituted, for example, of a laminate obtained by laminating a first active layer containing an electron donating compound and a second active layer containing an electron accepting compound. In this case, the first active layer is placed closer to an anode than the second active layer.

The organic photoelectric conversion device may have a constitution in which a plurality of active layers are laminated via an intermediate layer. In such a case, a multifunction type device (tandem type device) is obtained. In this case, each active layer may be a single layer type containing an electron accepting compound and an electron donating compound, or may be a laminated type constituted of a laminate obtained by laminating a first active layer containing an electron donating compound and a second active layer containing an electron accepting compound.

The intermediate layer can take the form of a single layer or the form of a laminate of a plurality of layers. The intermediate layer is constituted of so-called a charge injection layer or a charge transporting layer. As the intermediate layer, for example, a functional layer containing an electron transportable material described later can be used.

It is preferable that the active layer is formed by an application method. It is preferable that the active layer contains a polymer compound, and a polymer compound may be contained singly or two or more polymer compounds may be contained in combination. For enhancing the charge transportability of the active layer, an electron donating compound and/or an electron accepting compound may be mixed in the above-described active layer.

The electron accepting compound used in an organic photoelectric conversion device is composed of a compound having its HOMO energy higher than the HOMO energy of an electron donating compound and having its LUMO energy higher than the LUMO energy of an electron donating compound.

The above-described electron donating compound may be a low molecular weight compound or a polymer compound. The low molecular weight electron donating compound includes phthalocyanine, metallophthalocyanine, porphyrin, metalloporphyrin, oligothiophene, tetracene, pentacene, rubrene and the like.

The polymer electron donating compound includes polyvinylcarbazole and derivatives thereof, polysilane and derivatives thereof, polysiloxane derivatives having an aromatic amine in the side chain or main chain, polyaniline and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, and the like.

The above-described electron accepting compound may be a low molecular weight compound or a polymer compound. The low molecular weight electron accepting compound includes oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ and the like and derivatives thereof, phenanthrene derivatives such as bathocuproine and the like, etc. The polymer electron accepting compound includes polyvinylcarbazole and derivatives thereof, polysilane and derivatives thereof, polysiloxane derivatives having an aromatic amine in the side chain or main chain, polyaniline and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, and the like. Of them, fullerenes and derivatives thereof are especially preferable.

The fullerenes include C₆₀, C₇₀, carbon nanotubes, and derivatives thereof. Specific structures of the C₆₀ fullerene derivatives include those as shown below.

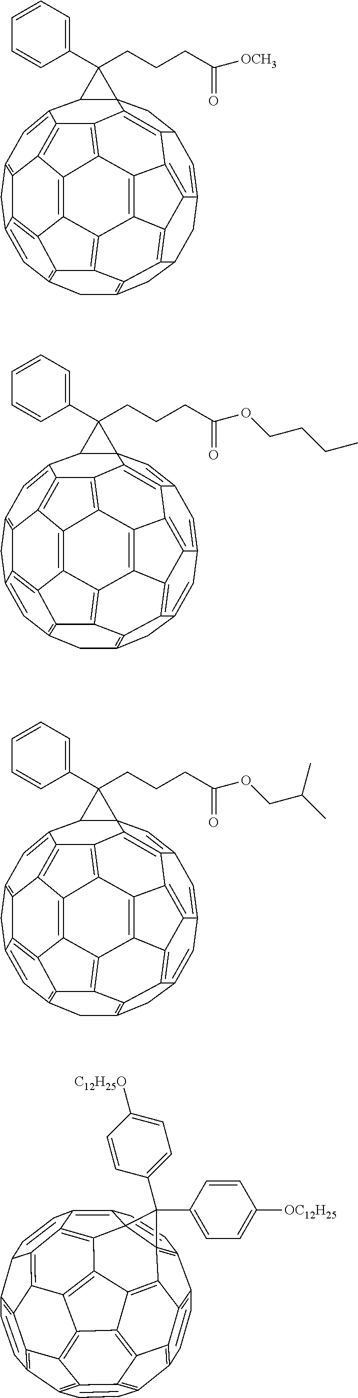

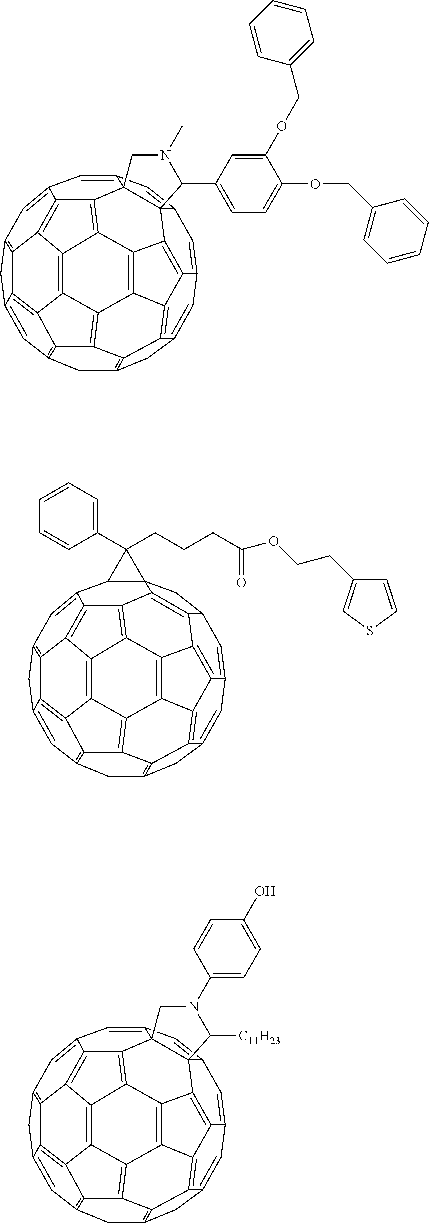

In a constitution wherein the active layer contains an electron accepting compound composed of fullerenes and/or derivatives of fullerenes and an electron donating compound, the proportion of fullerenes and derivatives of fullerenes is preferably 10 to 1000 parts by weight, more preferably 50 to 500 parts by weight with respect to 100 parts by weight of the electron donating compound. The organic photoelectric conversion device preferably has an active layer of a single layer constitution described above, and from the standpoint of much inclusion of the heterojunction interface, more preferably has an active layer of a single layer constitution containing an electron accepting compound composed of fullerenes and/or derivatives of fullerenes and an electron donating compound.

The active layer preferably contains a conjugated polymer compound, more preferably contains a conjugated polymer compound and fullerenes and/or derivatives of fullerenes. The conjugated polymer compound used in the active layer includes polythiophene and derivatives thereof, polyphenylenevinylene and derivatives thereof, polyfluorene and derivatives thereof, and the like.

The conjugated polymer compound contained in the active layer is preferably a conjugated polymer compound having a constitutional unit represented by the formula (1).

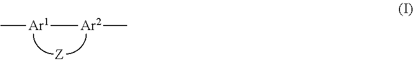

In the formula (I), Z represents a group represented by any one of the formula (Z-1) to the formula (Z-7) described below. Ar¹ and Ar² may be the same or different, and represent a trivalent aromatic heterocyclic group.

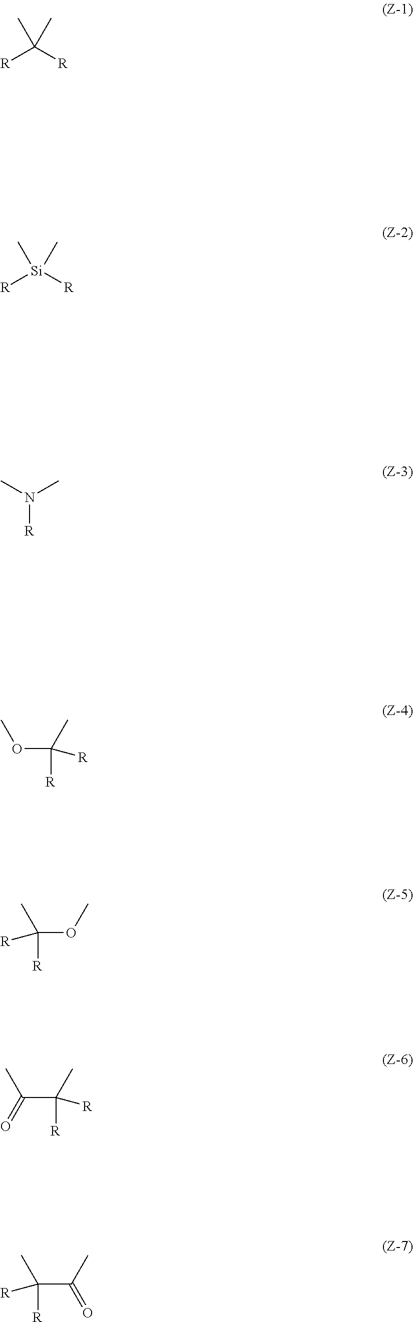

In the formula (Z-1) to the formula (Z-7), R represents a hydrogen atom, a halogen atom, an amino group, a cyano group or a monovalent organic group. The monovalent organic group includes, for example, an optionally substituted alkyl group, an optionally substituted alkoxy group, an optionally substituted alkylthio group, an aryl group, an aryloxy group, an arylthio group, an optionally substituted arylalkyl group, an optionally substituted arylalkoxy group, an optionally substituted arylalkylthio group, an optionally substituted acyl group, an optionally substituted acyloxy group, an optionally substituted amide group, an optionally substituted acid imide group, a substituted amino group, a substituted silyl group, a substituted silyloxy group, a substituted silylthio group, a substituted silylamino group, a monovalent heterocyclic group, a heterocyclicoxy group, a heterocyclicthio group, an arylalkenyl group, an arylalkynyl group and a carboxyl group. In each of the formula (Z-1) to the formula (Z-7), when two groups R are present, they may be the same or mutually different.

The halogen atom represented by R includes a fluorine atom, a chlorine atom, a bromine atom and an iodine atom, preferably a fluorine atom.

The optionally substituted alkyl group may be linear or branched, and may also be a cycloalkyl group. The alkyl group has a number of carbon atoms of usually 1 to 30. The substituent which the alkyl group optionally has includes, for example, a halogen atom. Specific examples of the halogen atom are the same as specific examples of the halogen atom represented by R. Specific examples of the optionally substituted alkyl group include linear alkyl groups such as a methyl group, an ethyl group, a propyl group, an isopropyl group, a butyl group, an isobutyl group, a sec-butyl group, a tert-butyl group, a pentyl group, an isopentyl group, a 2-methylbutyl group, a 1-methylbutyl group, a hexyl group, an isohexyl group, a 3-methylpentyl group, a 2-methylpentyl group, a 1-methylpentyl group, a heptyl group, an octyl group, an isooctyl group, a 2-ethylhexyl group, a 3,7-dimethyloctyl group, a nonyl group, a decyl group, an undecyl group, a dodecyl group, a tetradecyl group, a hexadecyl group, an octadecyl group, an eicosyl group and the like, and cycloalkyl groups such as a cyclopentyl group, a cyclohexyl group, an adamantyl group and the like.

The optionally substituted alkoxy group may be linear or branched, and may also be a cycloalkoxy group. The substituent which the alkoxy group optionally has includes, for example, a halogen atom. Specific examples of the halogen atom are the same as specific examples of the halogen atom represented by R. The alkoxy group has a number of carbon atoms of usually about 1 to 20. Specific examples of the optionally substituted alkoxy group include a methoxy group, an ethoxy group, a propoxy group, an isopropoxy group, a butoxy group, an isobutoxy group, a tert-butoxy group, a pentyloxy group, a hexyloxy group, a cyclohexyloxy group, a heptyloxy group, an octyloxy group, a 2-ethylhexyloxy group, a nonyloxy group, a decyloxy group, a 3,7-dimethyloctyloxy group, a lauryloxy group, a trifluoromethoxy group, a pentafluoroethoxy group, a perfluorobutoxy group, a perfluorohexyloxy group, a perfluorooctyloxy group, a methoxymethyloxy group and a 2-methoxyethyloxy group.

The optionally substituted alkylthio group may be linear or branched, and may also be a cycloalkylthio group. The substituent which the alkylthio group optionally has includes, for example, a halogen atom. Specific examples of the halogen atom are the same as specific examples of the halogen atom represented by R. The alkylthio group has a number of carbon atoms of usually about 1 to 20. Specific examples of the optionally substituted alkylthio group include a methylthio group, an ethylthio group, a propylthio group, an isopropylthio group, a butylthio group, an isobutylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group, a laurylthio group and a trifluoromethylthio group.

The aryl group is an atomic group obtained by removing from an optionally substituted aromatic hydrocarbon one hydrogen atom on the aromatic ring, and has a number of carbon atoms of usually 6 to 60. The substituent includes, for example, a halogen atom, an optionally substituted alkoxy group and an optionally substituted alkylthio group. Specific examples of the halogen atom, the optionally substituted alkoxy group and the optionally substituted alkylthio group are the same as specific examples of the halogen atom, the optionally substituted alkyl group, the optionally substituted alkoxy group and the optionally substituted alkylthio group represented by R. Specific examples of the aryl group include a phenyl group, a C1 to C12 alkyloxyphenyl group (The C1 to C12 alkyl denotes an alkyl having a number of carbon atoms of 1 to 12. The C1 to C12 alkyl is preferably a C1 to C8 alkyl, more preferably a C1 to C6 alkyl. The C1 to C8 alkyl denotes an alkyl having a number of carbon atoms of 1 to 8, and the C1 to C6 alkyl denotes an alkyl having a number of carbon atoms of 1 to 6. Specific examples of the C1 to C12 alkyl, the C1 to C8 alkyl and the C1 to C6 alkyl include those explained and exemplified for the above-described alkyl group. The same shall apply hereinafter.), a C1 to C12 alkylphenyl group, a 1-naphthyl group, a 2-naphthyl group and a pentafluorophenyl group.

The aryloxy group has a number of carbon atoms of usually about 6 to 60. Specific examples of the aryloxy group include a phenoxy group, a C1 to C12 alkyloxyphenoxy group, a C1 to C12 alkylphenoxy group, a 1-naphthyloxy group, a 2-naphthyloxy group and a pentafluorophenyloxy group.

The arylthio group has a number of carbon atoms of usually about 6 to 60. Specific examples of the arylthio group include a phenylthio group, a C1 to C12 alkyloxyphenylthio group, a C1 to C12 alkylphenylthio group, a 1-naphthylthio group, a 2-naphthylthio group and a pentafluorophenylthio group.

The optionally substituted arylalkyl group has a number of carbon atoms of usually about 7 to 60, and the alkyl portion optionally has a substituent. The substituent includes, for example, a halogen atom. Specific examples of the halogen atom are the same as specific examples of the halogen atom represented by R. Specific examples of the optionally substituted arylalkyl group include a phenyl-C1 to C12 alkyl group, a C1 to C12 alkyloxyphenyl-C1 to C12 alkyl group, a C1 to C12 alkylphenyl-C1 to C12 alkyl group, a 1-naphthyl-C1 to C12 alkyl group and a 2-naphthyl-C1 to C12 alkyl group.

The optionally substituted arylalkoxy group has a number of carbon atoms of usually about 7 to 60, and the alkoxy portion optionally has a substituent. The substituent includes, for example, a halogen atom. Specific examples of the halogen atom are the same as specific examples of the halogen atom represented by R. Specific examples of the optionally substituted arylalkyloxy group include a phenyl-C1 to C12 alkyloxy group, a C1 to C12 alkyloxyphenyl-C1 to C12 alkyloxy group, a C1 to C12 alkylphenyl-C1 to C12 alkyloxy group, a 1-naphthyl-C1 to C12 alkyloxy group and a 2-naphthyl-C1 to C12 alkyloxy group.

The optionally substituted arylalkylthio group has a number of carbon atoms of usually about 7 to 60, and the alkylthio portion optionally has a substituent. The substituent includes, for example, a halogen atom. Specific examples of the halogen atom are the same as specific examples of the halogen atom represented by R. Specific examples of the optionally substituted arylalkylthio group include a phenyl-C1 to C12 alkylthio group, a C1 to C12 alkyloxyphenyl-C1 to C12 alkylthio group, a C1 to C12 alkylphenyl-C1 to C12 alkylthio group, a 1-naphthyl-C1 to C12 alkylthio group and a 2-naphthyl-C1 to C12 alkylthio group.

The optionally substituted acyl group has a number of carbon atoms of usually about 2 to 20. The substituent which the acyl group optionally has includes, for example, a halogen atom. Specific examples of the halogen atom are the same as specific examples of the halogen atom represented by R. Specific examples of the optionally substituted acyl group include an acetyl group, a propionyl group, a butyryl group, an isobutyryl group, a pivaloyl group, a benzoyl group, a trifluoroacetyl group and a pentafluorobenzoyl group.

The optionally substituted acyloxy group has a number of carbon atoms of usually about 2 to 20. The substituent which the acyloxy group optionally has includes, for example, a halogen atom. Specific examples of the halogen atom are the same as specific examples of the halogen atom represented by R. Specific examples of the optionally substituted acyloxy group include an acetoxy group, a propionyloxy group, a butyryloxy group, an isobutyryloxy group, a pivaloyloxy group, a benzoyloxy group, a trifluoroacetyloxy group and a pentafluorobenzoyloxy group.

The optionally substituted amide group has a number of carbon atoms of usually about 1 to 20. The amide group denotes a group obtained by removing from an amide a hydrogen atom bonded to its nitrogen atom. The substituent which the amide group optionally has includes, for example, a halogen atom. Specific examples of the halogen atom are the same as specific examples of the halogen atom represented by R. Specific examples of the optionally substituted amide group include a formamide group, an acetamide group, a propioamide group, a butyroamide group, a benzamide group, a trifluoroacetamide group, a pentafluorobenzamide group, a diformamide group, a diacetamide group, a dipropioamide group, a dibutyroamide group, a dibenzamide group, a ditrifluoroacetamide group and a dipentafluorobenzamide group.

The optionally substituted acid imide group has a number of carbon atoms of usually about 2 to 20. The acid imide group denotes a group obtained by removing from an acid imide a hydrogen atom bonded to its nitrogen atom. The substituent which the acid imide group optionally has includes, for example, a halogen atom. Specific examples of the halogen atom are the same as specific examples of the halogen atom represented by R. Specific examples of the optionally substituted acid imide group include a succinimide group and a phthalic imide group.

The substituted amino group has a number of carbon atoms of usually about 1 to 40. The substituent which the substituted amino group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted amino group include a methylamino group, a dimethylamino group, an ethylamino group, a diethylamino group, a propylamino group, a dipropylamino group, an isopropylamino group, a diisopropylamino group, a butylamino group, an isobutylamino group, a tert-butylamino group, a pentylamino group, a hexylamino group, a cyclohexylamino group, a heptylamino group, an octylamino group, a 2-ethylhexylamino group, a nonylamino group, a decylamino group, a 3,7-dimethyloctylamino group, a laurylamino group, a cyclopentylamino group, a dicyclopentylamino group, a cyclohexylamino group, a dicyclohexylamino group, a pyrrolidyl group, a piperidyl group, a ditrifluoromethylamino group, a phenylamino group, a diphenylamino group, a C1 to C12 alkyloxyphenylamino group, a di(C1 to C12 alkyloxyphenyl)amino group, a di(C1 to C12 alkylphenyl)amino group, a 1-naphthylamino group, a 2-naphthylamino group, a pentafluorophenylamino group, a pyridylamino group, a pyridazinylamino group, a pyrimidylamino group, a pyrazylamino group, a triazylamino group, a phenyl-C1 to C12 alkylamino group, a C1 to C12 alkyloxyphenyl-C1 to C12 alkylamino group, a C1 to C12 alkylphenyl-C1 to C12 alkylamino group, a di(C1 to C12 alkyloxyphenyl-C1 to C12 alkyl)amino group, a di(C1 to C12 alkylphenyl-C1 to C12 alkyl)amino group, a 1-naphthyl-C1 to C12 alkylamino group and a 2-naphthyl-C1 to C12 alkylamino group.

The substituted silyl group has a number of carbon atoms of usually about 3 to 40. The substituent which the substituted silyl group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted silyl group include a trimethylsilyl group, a triethylsilyl group, a tripropylsilyl group, a triisopropylsilyl group, a tert-butyldimethylsilyl group, a triphenylsilyl group, a tri-p-xylylsilyl group, a tribenzylsilyl group, a diphenylmethylsilyl group, a tert-butyldiphenylsilyl group and a dimethylphenylsilyl group.

The substituted silyloxy group has a number of carbon atoms of usually about 3 to 40. The substituent which the substituted silyloxy group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted silyloxy group include a trimethylsilyloxy group, a triethylsilyloxy group, a tripropylsilyloxy group, a triisopropylsilyloxy group, a tert-butyldimethylsilyloxy group, a triphenylsilyloxy group, a tri-p-xylylsilyloxy group, a tribenzylsilyloxy group, a diphenylmethylsilyloxy group, a tert-butyldiphenylsilyloxy group and a dimethylphenylsilyloxy group.

The substituted silylthio group has a number of carbon atoms of usually about 3 to 40. The substituent which the substituted silylthio group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted silylthio group include a trimethylsilylthio group, a triethylsilylthio group, a tripropylsilylthio group, a triisopropylsilylthio group, a tert-butyldimethylsilylthio group, a triphenylsilylthio group, a tri-p-xylylsilylthio group, a tribenzylsilylthio group, a diphenylmethylsilylthio group, a tert-butyldiphenylsilylthio group and a dimethylphenylsilylthio group.

The substituted silylamino group has a number of carbon atoms of usually about 3 to 80. The substituent which the substituted silylamino group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted silylamino group include a trimethylsilylamino group, a triethylsilylamino group, a tripropylsilylamino group, a triisopropylsilylamino group, a tert-butyldimethylsilylamino group, a tri-phenylsilylamino group, a tri-p-xylylsilylamino group, a tribenzylsilylamino group, a diphenylmethylsilylamino group, a tert-butyldiphenylsilylamino group, a dimethylphenylsilylamino group, a di(trimethylsilyl)amino group, a di(triethylsilyl)amino group, a di(tripropylsilyl)amino group, a di(triisopropylsilyl)amino group, a di(tert-butyldimethylsilyl)amino group, a di(tri-phenylsilyl)amino group, a di(tri-p-xylylsilyl)amino group, a di(tribenzylsilyl)amino group, a di(diphenylmethylsilyl)amino group, a di(tert-butyldiphenylsilyl)amino group and a di(dimethylphenylsilyl)amino group.

The monovalent heterocyclic group is an atomic group obtained by removing from an optionally substituted heterocyclic compound one hydrogen atom on the hetero ring. The monovalent heterocyclic group has a number of carbon atoms of usually 4 to 20. The heterocyclic compound includes, for example, furan, thiophene, pyrrole, pyrroline, pyrrolidine, oxazole, isooxazole, triazole, isothiazole, imidazole, imidazoline, imidazolidine, pyrazole, pyrazoline, pyrazolidine, furazan, triazole, thiadiazole, oxadiazole, tetrazole, pyran, pyridine, piperidine, thiopyran, pyridazine, pyrimidine, pyrazine, piperazine, morpholine, triazine, benzofuran, isobenzofuran, benzothiophene, indole, isoindole, indolizine, indoline, isoindoline, chromene, chromane, isochromane, benzopyran, quinoline, isoquinoline, quinolizine, benzoimidazole, benzothiazole, indazole, naphthyridine, quinoxaline, quinazoline, quinazolidine, cinnoline, phthalazine, purine, pteridine, carbazole, xanthene, phenanthridine, acridine, p-carboline, perimidine, phenanthroline, thianthrene, phenoxathiin, phenoxazine, phenothiazine and phenazine. The substituent which the heterocyclic compound optionally has includes, for example, a halogen atom, an optionally substituted alkyl group, an optionally substituted alkoxy group and an optionally substituted alkylthio group. Specific examples of the halogen atom, the optionally substituted alkyl group, the optionally substituted alkoxy group and substituted and the optionally substituted alkylthio group are the same as specific examples of the halogen atom, the optionally substituted alkyl group, the optionally substituted alkoxy group and the optionally substituted alkylthio group represented by R. The heterocyclic group is preferably an aromatic heterocyclic group.

The heterocyclicoxy group includes a group represented by the formula (A-1) obtained by bonding of an oxygen atom to the above-described monovalent heterocyclic group.

The heterocyclicthio group includes a group represented by the formula (A-2) obtained by bonding of a sulfur atom to the above-described monovalent heterocyclic group.

Ar³—O— (A-1)

Ar³—S— (A-2)

(in the formula (A-1) and the formula (A-2), Ar³ represents a monovalent heterocyclic group.)

Specific examples of the heterocyclicoxy group include a thienyloxy group, a C1 to C12 alkylthienyloxy group, a pyrrolyloxy group, a furyloxy group, a pyridyloxy group, a C1 to C12 alkylpyridyloxy group, an imidazolyloxy group, a pyrazolyloxy group, a triazolyloxy group, an oxazolyloxy group, a thiazoleoxy group and a thiadiazoleoxy group.

Specific examples of the heterocyclicthio group include a thienylmercapto group, a C1 to C12 alkylthienylmercapto group, a pyrrolylmercapto group, a furylmercapto group, a pyridylmercapto group, a C1 to C12 alkylpyridylmercapto group, an imidazolylmercapto group, a pyrazolylmercapto group, a triazolylmercapto group, an oxazolylmercapto group, a thiazolemercapto group and a thiadiazolemercapto group.

The arylalkenyl group usually has a number of carbon atoms of 8 to 20. Specific examples of the arylalkenyl group include a styryl group.

The arylalkynyl group usually has a number of carbon atoms of 8 to 20. Specific examples of the arylalkynyl group include a phenylacetylenyl group.

The trivalent aromatic heterocyclic group represented by Ar¹ and Ar² denotes an atomic group remaining after removing from an optionally substituted heterocyclic compound having aromaticity three hydrogen atoms on the aromatic ring.

The trivalent aromatic heterocyclic group has a number of carbon atoms of usually 2 to 60, preferably 4 to 60, more preferably 4 to 20.

The substituent which the heterocyclic compound having aromaticity optionally has includes, for example, a halogen atom, an amino group, a cyano group and a monovalent organic group. The definition and specific examples of the halogen atom and the monovalent organic group are the same as the definition and specific examples of the halogen atom and the monovalent organic group represented by R.

Specific examples of the trivalent aromatic heterocyclic group represented by Ar¹ and Ar² include the formula (201) to the formula (301) show below.

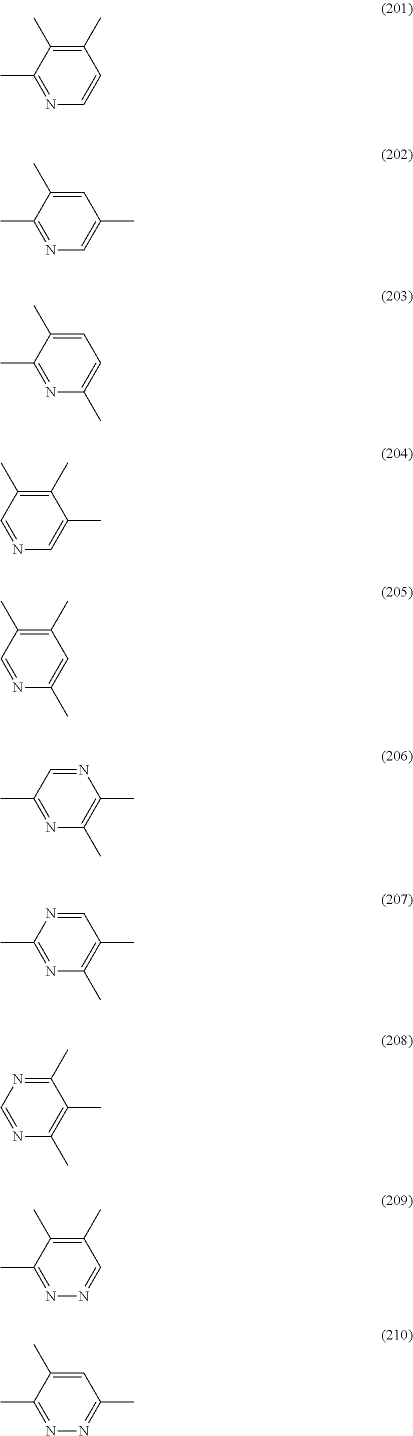

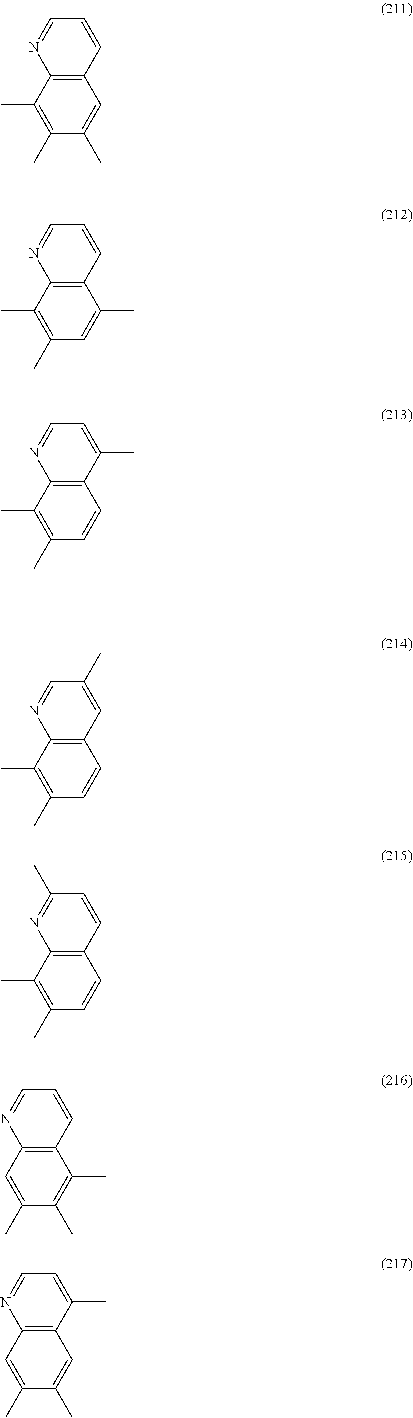

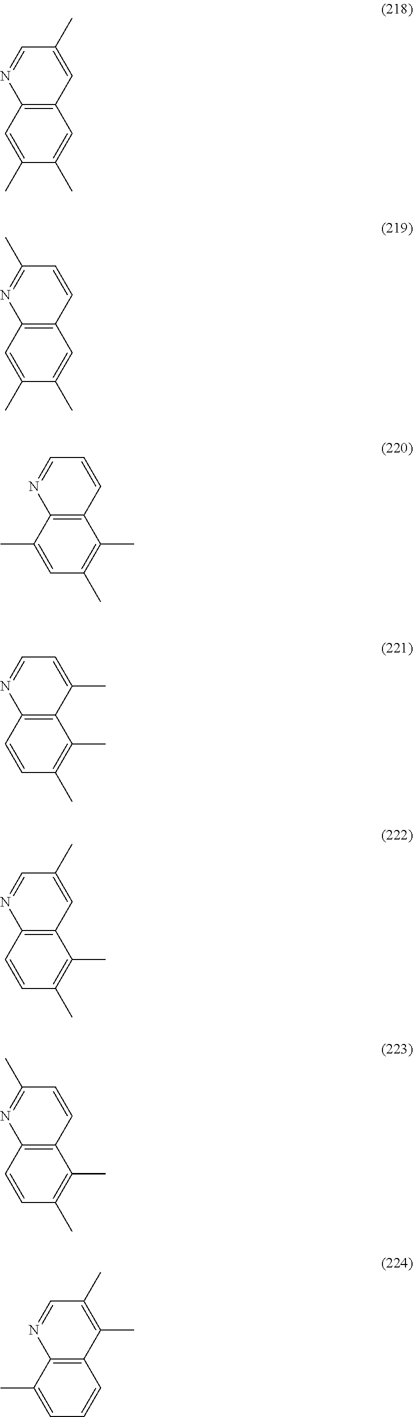

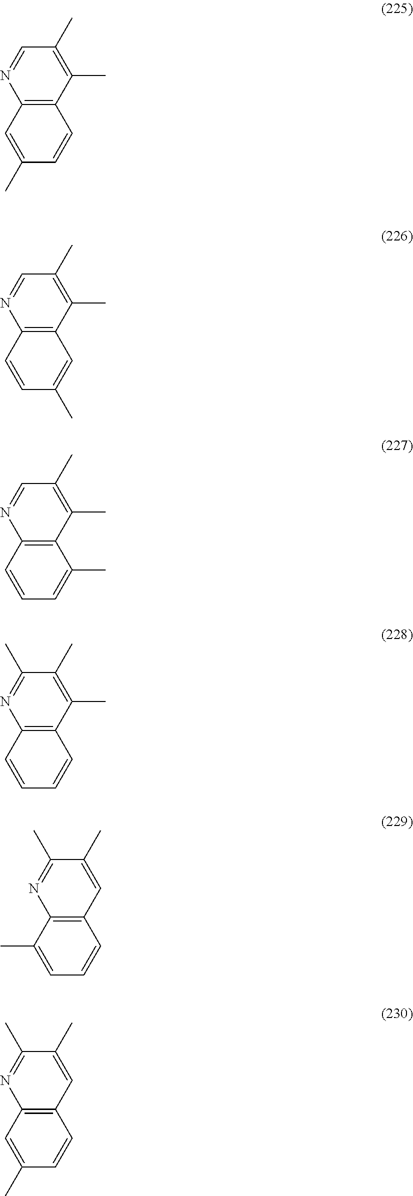

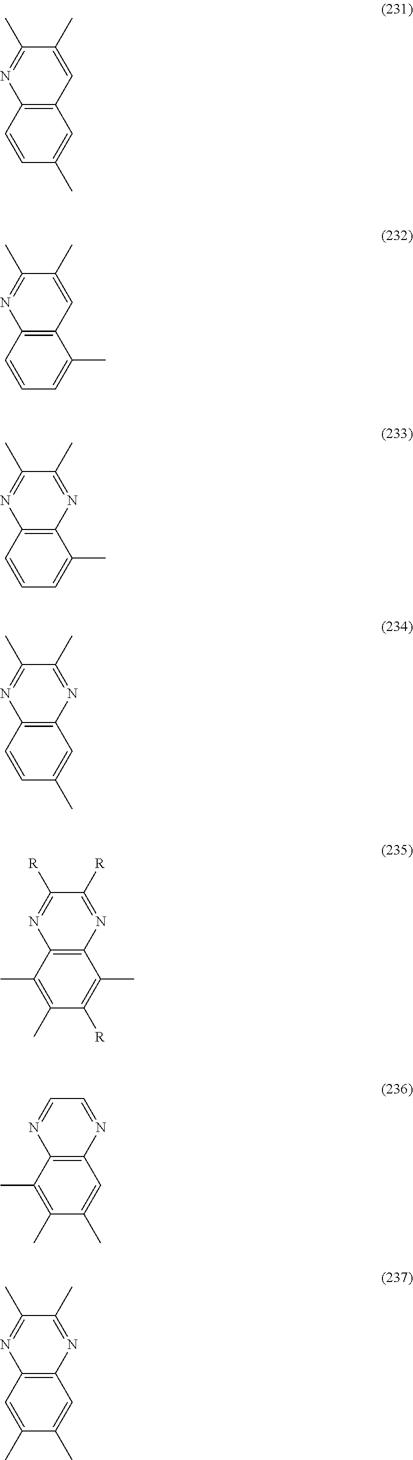

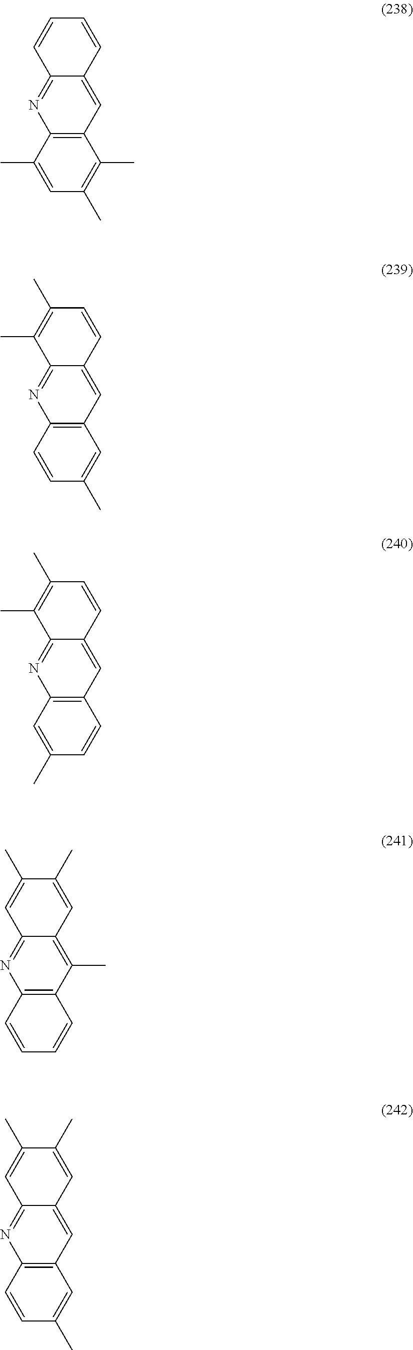

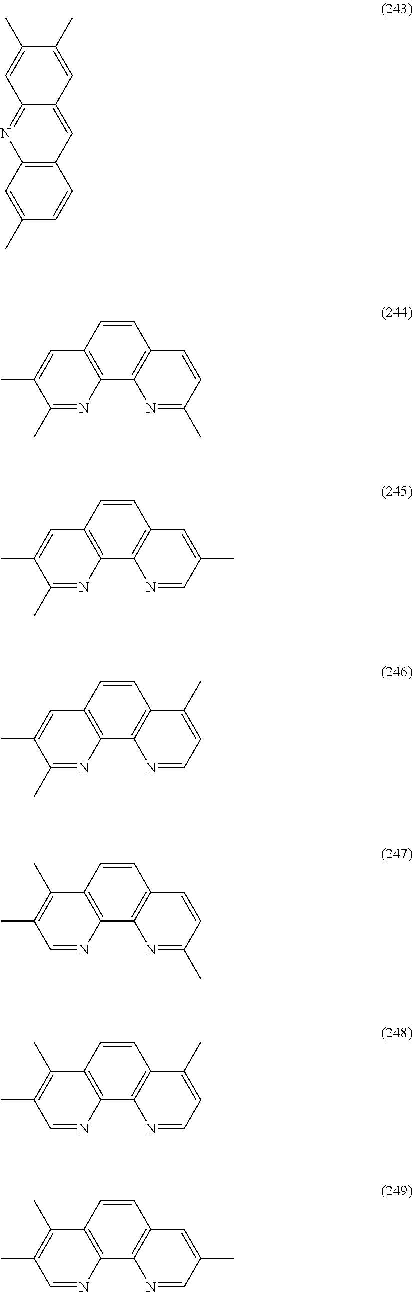

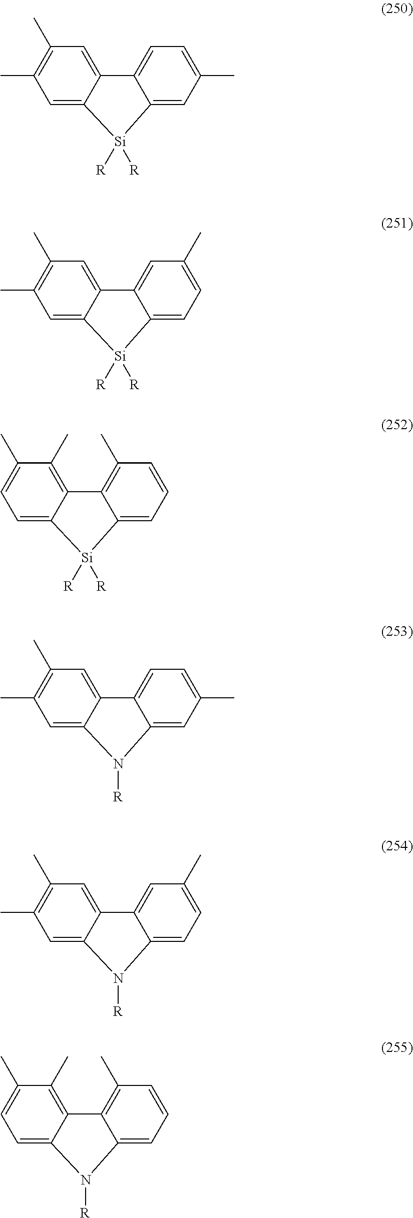

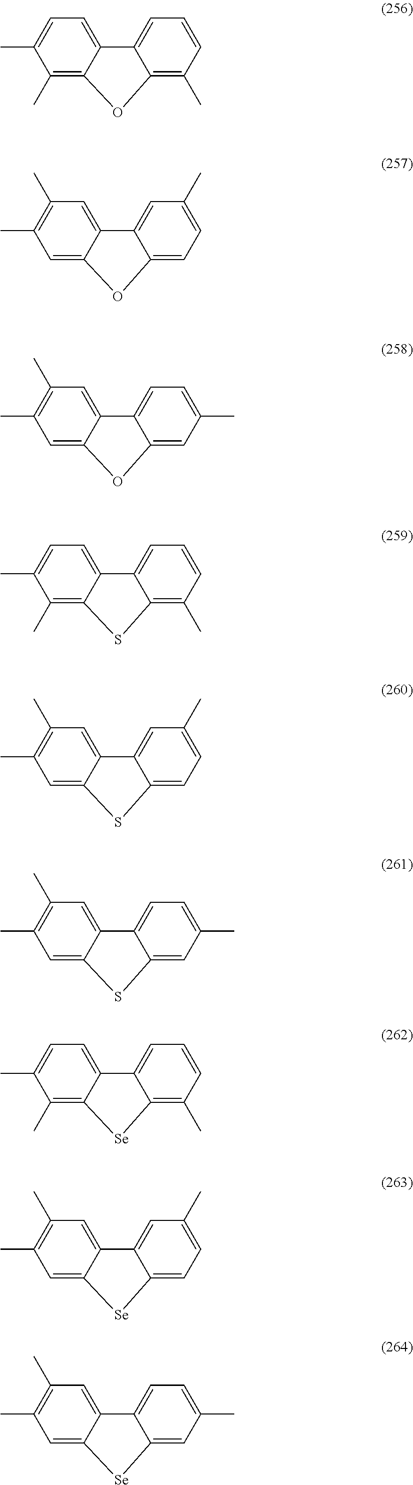

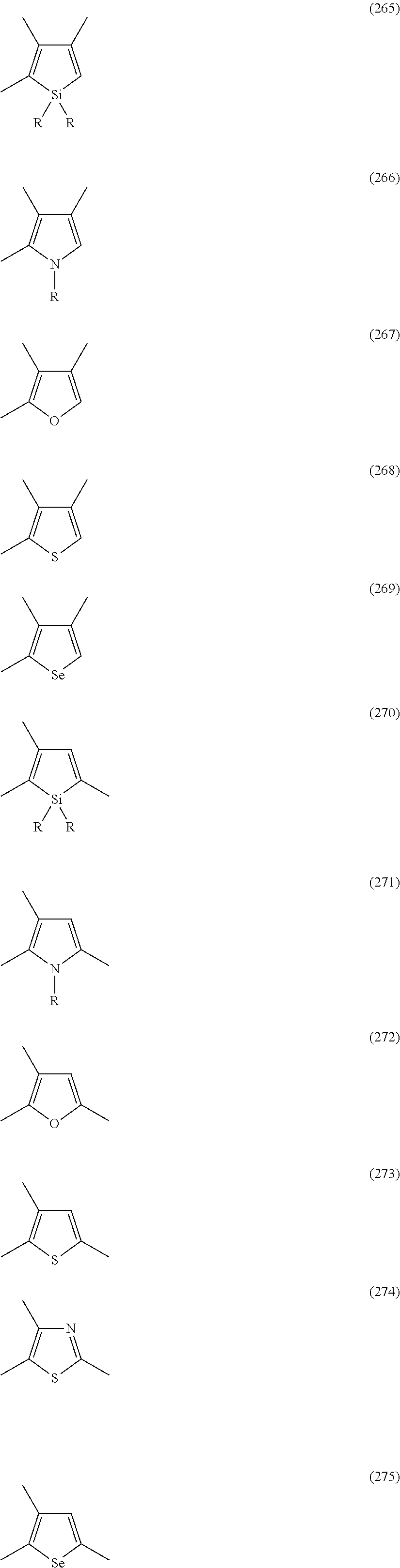

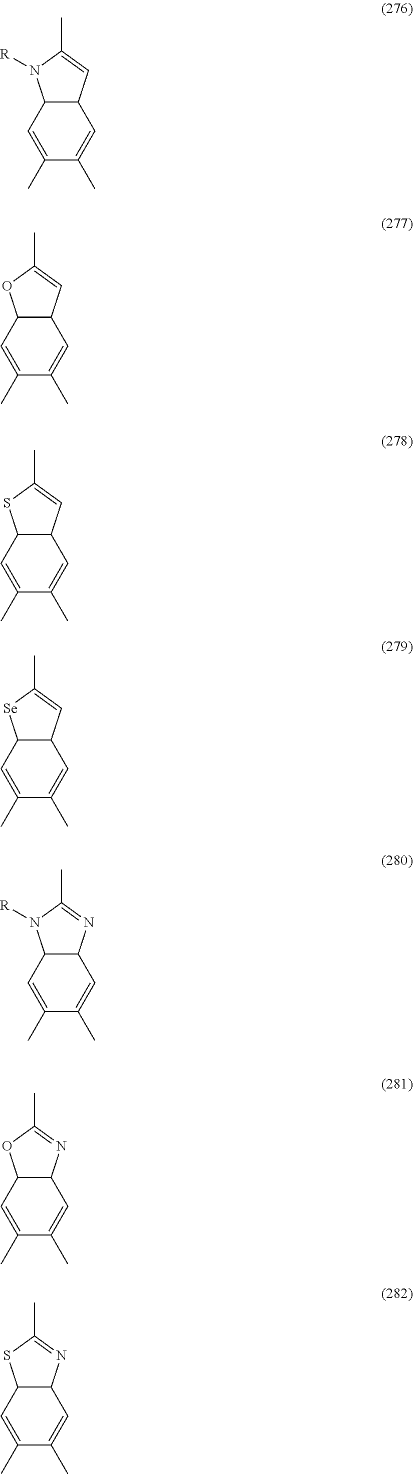

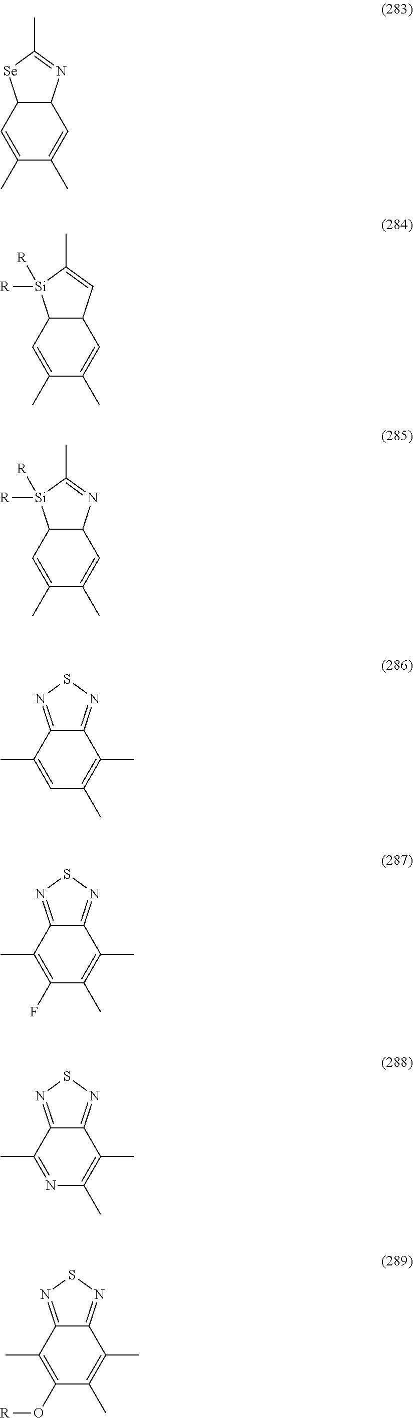

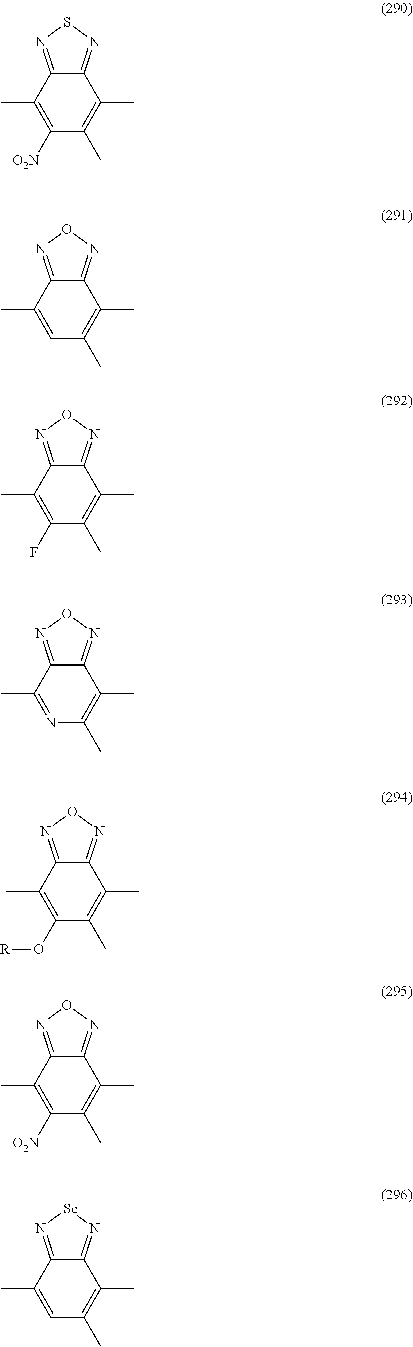

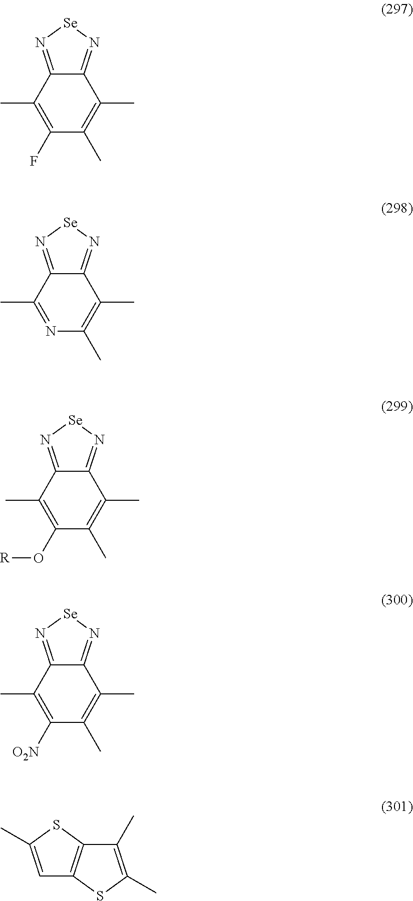

(wherein, R represents the same meaning as described above. When a plurality of R are present, they may be the same or different.)

Of groups represented by the formula (201) to the formula (301), groups represented by the formula (202), the formula (205), the formula (206), the formula (207), the formula (210), the formula (212), the formula (220), the formula (235), the formula (238), the formula (270), the formula (271), the formula (272), the formula (273), the formula (274), the formula (275), the formula (286), the formula (287), the formula (288), the formula (291), the formula (292), the formula (293), the formula (296) and the formula (301) are preferable, groups represented by the formula (235), the formula (271), the formula (272), the formula (273), the formula (274), the formula (286), the formula (291), the formula (296) and the formula (301) are more preferable, groups represented by the formula (271), the formula (272), the formula (273) and the formula (274) are further preferable, a group represented by the formula (273) is particularly preferable, from the standpoint of obtaining a highly efficient photoelectric conversion device.

The above-described constitutional unit represented by the formula (1) is preferably a constitutional unit represented by the following formula (2).

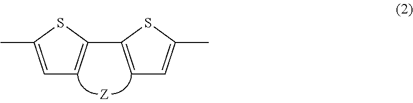

[in the formula (2), Z represents the same meaning as described above.]

The constitutional unit represented by the formula (2) includes, for example, constitutional units represented by the formula (501) to the formula (505).

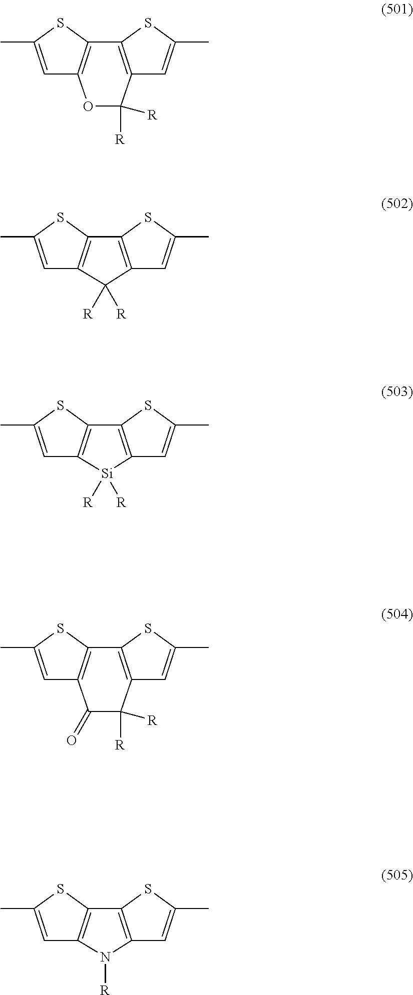

[wherein, R represents the same meaning as described above. When two groups R are present, they may be the same or different.]

Of constitutional units represented by the formula (501) to the formula (505) described above, constitutional units represented by the formula (501), the formula (502), the formula (503) and the formula (504) are preferable, constitutional units represented by the formula (501) and the formula (504) are more preferable, a constitutional unit represented by the formula (501) is particularly preferable, from the standpoint of obtaining a highly efficient photoelectric conversion device.

The conjugated polymer compound having a constitutional unit represented by the formula (1) may have other constitutional units. The other constitutional unit includes, for example, a constitutional unit represented by the formula (3).

—Ar⁴— (3)

[Ar⁴ represents an arylene group optionally having a substituent or a divalent heterocyclic group optionally having a substituent.]

In the arylene group optionally having a substituent represented by Ar⁴, the arylene group is a group obtained by removing from an aromatic hydrocarbon two hydrogen atoms. The arylene group has a number of carbon atoms of usually 6 to 60. The substituent includes a halogen atom, an alkyl group (for example, having a number of carbon atoms of 1 to 20), a cycloalkyl group (for example, having a number of carbon atoms of 3 to 20), an alkoxy group (for example, having a number of carbon atoms of 1 to 20) and a cycloalkoxy group (for example, having a number of carbon atoms of 3 to 20). As the halogen atom, a fluorine atom is preferable.

Specific examples of the arylene group optionally having a substituent include a phenylene group optionally having a substituent, a naphthalenediyl group optionally having a substituent, an anthracenediyl group optionally having a substituent, a biphenyldiyl group optionally having a substituent, a terphenyldiyl group optionally having a substituent and a condensed ring compound group optionally having a substituent. The condensed ring compound group includes a fluorenediyl group.

The divalent heterocyclic group optionally having a substituent represented by Ar⁴ has a number of carbon atoms of usually 2 to 60, preferably 4 to 60, more preferably 4 to 20. The hetero ring of the divalent heterocyclic group includes, for example, groups obtained by removing two hydrogen atoms from a heterocyclic compound selected from the group consisting of furan, thiophene, pyrrole, pyrroline, pyrrolidine, oxazole, isooxazole, triazole, isothiazole, imidazole, imidazoline, imidazolidine, pyrazole, pyrazoline, pyrazolidine, furazan, triazole, thiadiazole, oxadiazole, tetrazole, pyran, pyridine, piperidine, thiopyran, pyridazine, pyrimidine, pyrazine, piperazine, morpholine, triazine, benzofuran, isobenzofuran, benzothiophene, indole, isoindole, indolizine, indoline, isoindoline, chromene, chromane, isochromane, benzopyran, quinoline, isoquinoline, quinolizine, benzoimidazole, benzothiazole, indazole, naphthyridine, quinoxaline, quinazoline, quinazolidine, cinnoline, phthalazine, purine, pteridine, carbazole, xanthene, phenanthridine, acridine, β-carboline, perimidine, phenanthroline, thianthrene, phenoxathiin, phenoxazine, phenothiazine and phenazine. The substituent includes, for example, a halogen atom, an alkyl group optionally having a substituent, a cycloalkyl group optionally having a substituent, an alkoxy group optionally having a substituent, a cycloalkoxy group optionally having a substituent, an alkylthio group optionally having a substituent, a cycloalkylthio group optionally having a substituent and an aryl group optionally having a substituent. The definition and specific examples of the halogen atom, the alkyl group optionally having a substituent, the cycloalkyl group optionally having a substituent, the alkoxy group optionally having a substituent, the cycloalkoxy group optionally having a substituent, the alkylthio group optionally having a substituent, the cycloalkylthio group optionally having a substituent and the aryl group optionally having a substituent are the same as the definition and specific examples of the halogen atom, the alkyl group optionally having a substituent, the cycloalkyl group optionally having a substituent, the alkoxy group optionally having a substituent, the cycloalkoxy group optionally having a substituent, the alkylthio group optionally having a substituent, the cycloalkylthio group optionally having a substituent and the aryl group optionally having a substituent represented by R¹ and R². The divalent heterocyclic group is preferably a divalent aromatic heterocyclic group.

Specific examples of the divalent heterocyclic group include the following groups: a pyridinediyl group optionally having a substituent, a diazaphenylene group optionally having a substituent, a quinolinediyl group optionally having a substituent, a quinoxalinediyl group optionally having a substituent, an acridinediyl group optionally having a substituent, a bipyridyldiyl group optionally having a substituent, a phenanthrolinediyl group optionally having a substituent, a group containing silicon, nitrogen, sulfur, selenium and the like as a hetero atom and having a fluorene structure, a 5-membered ring heterocyclic group containing silicon, nitrogen, sulfur, selenium and the like as a hetero atom, a 5-membered ring condensed hetero group containing silicon, nitrogen, sulfur, selenium and the like as a hetero atom, a 5-membered ring heterocyclic group containing silicon, nitrogen, sulfur, selenium and the like as a hetero atom, groups bonding at the α-position of a hetero atom to form a dimer or an oligomer, a group bonding at the α-position of a hetero atom to a phenyl group, and a group obtained by condensation of a benzene ring and a thiophene ring.

It is preferable that the conjugated polymer compound having a constitutional unit represented by the formula (1) further has a constitutional unit represented by the formula (3), from the standpoint of enhancing the photoelectric conversion efficiency of an organic photoelectric conversion device.

The constitutional unit represented by the formula (3) is preferably a constitutional unit represented by the formula (3-1), the formula (3-2), the formula (3-3), the formula (3-4), the formula (3-5), the formula (3-6), the formula (3-7) or the formula (3-8), more preferably a constitutional unit represented by the formula (3-2).

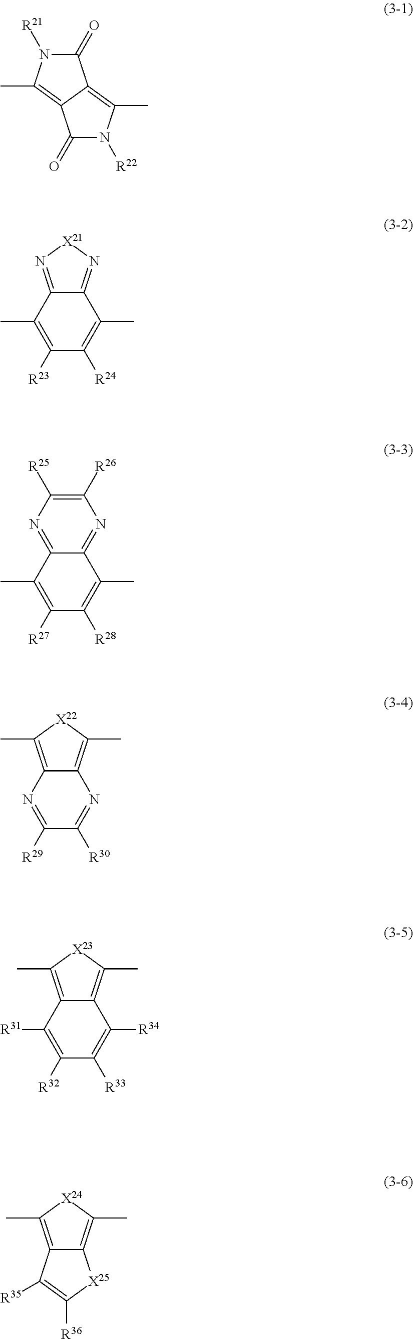

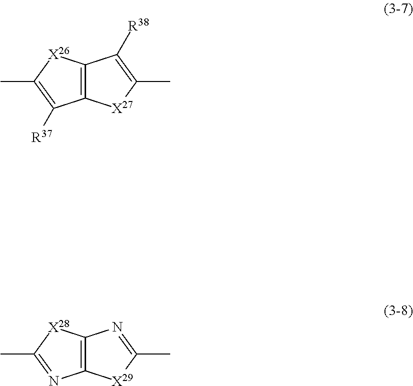

In the formula (3-1) to the formula (3-8), R²¹ to R³⁸ each independently represent a hydrogen atom, a halogen atom, an amino group, a cyano group, a nitro group or a monovalent organic group. The definition and specific examples of the halogen atom and the monovalent organic group represented by R²¹ to R³⁸ are the same as the definition and specific examples of the halogen atom and the monovalent organic group represented by R.

As R²¹, R²² and R³⁵, an alkyl group optionally having a substituent, a cycloalkyl group optionally having a substituent, an alkoxy group optionally having a substituent, a cycloalkoxy group optionally having a substituent, an aryl group optionally having a substituent, an aryloxy group optionally having a substituent, an arylalkyl group optionally having a substituent and an arylalkoxy group optionally having a substituent are preferable, an alkyl group optionally having a substituent, a cycloalkyl group optionally having a substituent, an aryl group optionally having a substituent and an arylalkyl group optionally having a substituent are more preferable, an alkyl group optionally having a substituent and a cycloalkyl group optionally having a substituent are further preferable.

As R²³, R²⁴, R²⁷, R²⁸, R³¹, R³², R³³, R³⁴, R³⁷ and R³⁸, a halogen atom and a hydrogen atom are preferable, a fluorine atom and a hydrogen atom are more preferable.

As R²⁵, R²⁶, R²⁹ and R³⁰, a hydrogen atom, a halogen atom, an alkyl group optionally having a substituent, a cycloalkyl group optionally having a substituent, an aryl group optionally having a substituent and an arylalkyl group optionally having a substituent are preferable, a hydrogen atom and an arylalkyl group optionally having a substituent are more preferable.

As R³⁶, a hydrogen atom, a halogen atom, an acyl group and an acyloxy group are preferable, an acyl group and an acyloxy group are more preferable.

In the formula (3-1) to the formula (3-8), X²¹ to X²⁹ each independently represent a sulfur atom, an oxygen atom or a selenium atom. As X²¹ to X²⁹, a sulfur atom and an oxygen atom are preferable, a sulfur atom is more preferable.

When the conjugated polymer compound has a constitutional unit represented by the formula (1) and a constitutional unit represented by the formula (3), the proportion of the constitutional unit represented by the formula (1) contained in the conjugated polymer compound is preferably 30 mol % to 70 mol % with respect to the sum of the constitutional unit represented by the formula (1) and the constitutional unit represented by the formula (3).

When the organic photoelectric conversion device of the present invention has two or more active layers, it is preferable that at least one of two active layers contains a conjugated polymer compound having a constitutional unit represented by the formula (1), and when both the layer A and the layer B are active layers, it is preferable that either the layer A or the layer B contains a conjugated polymer compound having a constitutional unit represented by the formula (1).

The conjugated polymer compound having a constitutional unit represented by the formula (1) and a constitutional unit represented by the formula (3) can be produced and used according to a method described in International Publication WO2013/051676A1.

In the present invention, the polymer compound denotes a compound having a weight-average molecular weight of 3000 or more. The weight-average molecular weight of the polymer compound is preferably 3000 to 10000000, more preferably 8000 to 5000000, further preferably 10000 to 1000000.

When the weight-average molecular weight of the polymer compound is smaller than 3000, coatability lowers in some cases when used for fabrication of a device. When the weight-average molecular weight is larger than 10000000, solubility in a solvent and coatability lower in some cases when used for fabrication of a device.

The weight-average molecular weight of the polymer compound denotes the polystyrene-equivalent weight-average molecular weight measured by gel permeation chromatography (GPC).

The polystyrene-equivalent number-average molecular weight of the polymer compound is preferably 1000 to 100000000. When the polystyrene-equivalent number-average molecular weight is 1000 or more, a tough film is obtained easily. When the polystyrene-equivalent number-average molecular weight is 100000000 or less, the solubility of the polymer compound is high and fabrication of a film is easy. The polystyrene-equivalent number-average molecular weight of the polymer compound is preferably 3000 or more.

The thickness of the active layer is usually 1 nm to 100 μm, preferably 2 nm to 1000 nm, more preferably 5 nm to 500 nm, further preferably 20 nm to 200 nm.

The organic photoelectric conversion device is not limited to the above-described device constitution, and an additional layer may be further provided between an anode and a cathode. The additional layer includes, for example, a charge transporting layer, and the charge transporting layer includes a hole transporting layer which transports holes and an electron transporting layer which transports electrons. For example, a hole transporting layer is provided between an anode and an active layer and an electron transporting layer is provided between a cathode and an active layer, thus, surface flattening and charge injection can be promoted.

As the material used in a hole transporting layer or an electron transporting layer as the above-described additional layer, electron donating compounds and electron accepting compounds described above respectively can be used, and halides, oxides and the like of alkali metals and alkaline earth metals such as lithium fluoride and the like can also be used.

The charge transporting layer can also be formed using fine particles of an inorganic semiconductor such as titanium oxide and the like.

For example, an electron transporting layer can be formed by forming a film of a titania solution by an application method on a foundation layer on which the electron transporting layer is to be formed and by further drying the film.

The hole transporting layer and the electron transporting layer as the additional layer will be specifically illustrated.

### (Electron Transporting Layer)

It is preferable for the organic photoelectric conversion device to have an electron transporting layer containing an electron transportable material between an active layer and a cathode.

The electron transporting layer is preferably formed by an application method, and for example, preferably formed by applying an application liquid containing an electron transportable material and a solvent on the surface of a layer on which the electron transporting layer is to be formed. In the present invention, the application liquid includes also dispersion liquids such as an emulsion (emulsified liquid), a suspension (suspended liquid) and the like.

The electron transportable material includes, for example, zinc oxide, titanium oxide, zirconium oxide, tin oxide, indium oxide, ITO (indium tin oxide), FTO (fluorine-doped tin oxide), GZO (gallium-doped zinc oxide), ATO (antimony-doped tin oxide) and AZO (aluminum-doped zinc oxide), and of them, zinc oxide is preferable. In forming an electron transporting layer, it preferable that an application liquid containing particulate zinc oxide is applied to form the electron transporting layer. As such an electron transporting material, so-called zinc oxide nanoparticles are preferably used, and it is more preferable to form an electron transporting layer using an electron transportable material composed singly of zinc oxide nanoparticles. The sphere equivalent average particle size of zinc oxide is preferably 1 nm to 1000 nm, preferably 10 nm to 100 nm. The average particle size is measured by a laser light scattering method and an X-ray diffraction method.

By providing an electron transporting layer containing an electron transportable material between a cathode and an active layer, peeling of a cathode can be prevented and efficiency of electron injection from an active layer into a cathode can be enhanced. It is preferable that an electron transporting layer is provided in contact with an active layer and further, it is preferable that an electron transporting layer is provided in contact also with a cathode. By providing an electron transporting layer containing an electron transportable material as described above, peeling of a cathode can be prevented and efficiency of electron injection from an active layer into a cathode can be further enhanced. By providing such an electron transporting layer, an organic photoelectric conversion device having high reliability and manifesting high photoelectric conversion efficiency can be realized.

By providing an electron transporting layer containing an electron transportable material, efficiency of injection of electrons into a cathode can be enhanced, injection of holes from an active layer can be prevented, performance of transporting electrons can be enhanced, an active layer can be protected from erosion by an application liquid used in forming a cathode by an application method after formation of an active layer, deterioration of an active layer can be suppressed.

It is preferable that the electron transporting layer containing an electron transportable material is constituted of a material having high wettability against an application liquid used in forming a cathode or an active layer by application after formation of an electron transporting layer. Specifically, it is preferable that the electron transporting layer containing an electron transportable material has high wettability against an application liquid used in forming a cathode or an active layer by application. By forming a cathode or an active layer on such an electron transporting layer by application, an application liquid wets and spreads successfully on the surface of an electron transporting layer in forming a cathode or an active layer and a cathode or an active layer having uniform thickness can be formed.

The method of forming a film of an application liquid includes the same method as for the above-described active layer.

### (Hole Transporting Layer)

It is preferable that the organic photoelectric conversion device has a hole transporting layer containing a hole transportable material between an active layer and a anode.

The hole transporting layer is preferably formed by an application method, and for example, preferably formed by applying an application liquid containing a hole transportable material and a solvent on the surface of a layer on which the hole transporting layer is to be provided. In the present invention, the application liquid includes also dispersion liquids such as an emulsion (emulsified liquid), a suspension (suspended liquid) and the like.

The function of the hole transporting layer includes a function of enhancing efficiency of injection of holes into an active layer, a function of preventing injection of electrons from an active layer, a function of enhancing performance of transportation of holes, a function of enhancing flatness, a function of protecting an active layer from erosion by an application liquid for forming a film of an anode when the anode is fabricated by an application method after formation of the active layer, a function of suppressing deterioration of an active layer, and the like.

The hole transportable material includes, for example, a polymer compound showing a function of transporting holes. Examples of the polymer compound showing a function of transporting holes include a polymer compound containing a thiophenediyl group, a polymer compound containing an anilinediyl group and a polymer compound containing a pyrrolediyl group. Of the polymer compounds showing a function of transporting holes, highly electrically conductive polymer compounds are preferable. The conductivity of the highly electrically conductive polymer compound is usually 10⁻⁵ to 10⁵ S/cm, preferably 10⁻³ to 10⁴ S/cm.

The polymer compound showing a function of transporting holes may have an acid group such as a sulfonate group and the like. Examples of the polymer compound having an acid group include poly(thiophene) having an acid group and poly(aniline) having an acid group. The poly(thiophene) having an acid group and the poly(aniline) having an acid group may further have a substituent other than an acid group.

The hole transporting layer may contain other polymer compounds as a binder in addition to the above-described polymer compound showing a function of transporting holes. The binder includes, for example, polystyrenesulfonic acid, polyvinylphenol, novolak resins and polyvinyl alcohol.

The method of forming a film of an application liquid includes the same method as for an active layer described later.

One embodiment of the organic photoelectric conversion device of the present invention is an organic photoelectric conversion device containing a transparent anode, a first active layer, an intermediate layer, a second active layer and a transparent cathode in this order, in which one of the first active layer and the second active layer is the layer A and the other is the layer B.

The layer A and the layer B satisfy (condition 1), preferably (condition 1-1), more preferably (condition 1-2).

The organic photoelectric conversion device of the present invention usually has a transparent substrate and/or a sealing layer.

One embodiment of the organic photoelectric conversion device of the present invention is an organic photoelectric conversion device containing a transparent substrate, a transparent anode, a first active layer, an intermediate layer, a second active layer, a transparent cathode and a transparent sealing layer in this order, in which one of the first active layer and the second active layer is the layer A and the other is the layer B.

One embodiment of the organic photoelectric conversion device of the present invention is an organic photoelectric conversion device containing a transparent sealing layer, a transparent anode, a first active layer, an intermediate layer, a second active layer, a transparent cathode and a transparent substrate in this order, in which one of the first active layer and the second active layer is the layer A and the other is the layer B.

The organic photoelectric conversion device of the present invention may have an additional layer such as a hole transporting layer and the like between a transparent anode and a first active layer and may have an additional layer such as an electron transporting layer and the like between a first active layer and a transparent cathode. The intermediate layer can take the form of a single layer or the form of a laminate of a plurality of layers.

The layer constituting the intermediate layer includes a layer containing an electron transportable material and a layer containing a hole transportable material. The intermediate layer having the form of a laminate includes an intermediate layer having the form of a laminate of a layer containing an electron transportable material and a layer containing a hole transportable material. The layer containing an electron transportable material of this intermediate layer having the form of a laminate is preferably situated at the transparent cathode side.

One embodiment of the organic photoelectric conversion device of the present invention is a laminated type organic photoelectric conversion device composed of a laminate of a first photoelectric conversion device having a first active layer between a pair of electrodes and a second photoelectric conversion device having a second active layer between a pair of electrodes, in which one of the first active layer and the second active layer is the layer A and the other is the layer B.

This laminated type organic photoelectric conversion device is obtained by superimposing a first organic photoelectric conversion device and a second organic photoelectric conversion device and installing wiring so as to connect prescribed electrodes.

The first organic photoelectric conversion device is an organic photoelectric conversion device containing a transparent anode, a first active layer and a transparent cathode in this order. The first organic photoelectric conversion device may have an additional layer such as a hole transporting layer and the like between a transparent anode and a first active layer and may have an additional layer such as an electron transporting layer and the like between a first active layer and a transparent cathode. The first organic photoelectric conversion device usually has a transparent substrate and a transparent sealing layer.

The second organic photoelectric conversion device is an organic photoelectric conversion device containing a transparent anode, a second active layer and a transparent cathode in this order. The second organic photoelectric conversion device usually has a transparent substrate and a transparent sealing layer.

When anodes of the first and second organic photoelectric conversion devices are mutually connected and cathodes thereof are mutually connected, parallel connection is formed, and the current values of the organic film photoelectric conversion devices are added. When, for example, a cathode and an anode of organic film photoelectric conversion devices having adjacent numbers are connected and current is taken out between an anode of the first organic film photoelectric conversion device and a cathode of the second organic film photoelectric conversion device, serial connection is formed, and the voltage values of the organic film photoelectric conversion devices are added. As a result, Jsc (short-circuit current density) or Voc (open end voltage) which is higher as compared with a single photoelectric conversion device can be obtained, and eventually, high photoelectric conversion efficiency can be obtained.

### <2> Production Method of Organic Photoelectric Conversion Device

The organic photoelectric conversion device of the present invention can be produced by sequentially laminating layers constituting the device.

The layer constituting the organic photoelectric conversion device of the present invention includes electrodes (transparent or semi-transparent anode and cathode); semiconductor layers such as an active layer, an electron transporting layer, a hole transporting layer, an intermediate layer and the like formed between transparent or semi-transparent anode and cathode; a sealing layer formed on an electrode if necessary; a toning layer formed in contact with a sealing layer or a supporting substrate if necessary; a supporting substrate; a protective layer, and the like.

The semiconductor layer other than an active layer can be formed according to the active layer.

Formation steps of an electrode, an active layer, a sealing layer and a toning layer are described below.

### <Electrode Formation Step>

The electrode is formed by forming a film of the exemplified electrode material on a supporting substrate described above by a vacuum vapor deposition method, a sputtering method, an ion plating method, a plating method and the like. The electrode may also be formed by an application method using an application liquid containing an organic material such as polyaniline and derivatives thereof, polythiophene and derivatives thereof and the like, an ink of nanoparticles of a metal oxide, an ink of a metal oxide precursor, metal nanowires, a metal ink, a metal past, a low melting metal in molten state and the like

### <Active Layer Formation Step>

The method of forming an active layer is not particularly restricted, and it is preferable to form an active layer by an application method from the standpoint of simplification of the production step. The active layer can be formed, for example, by an application method using an application liquid containing the above-described active layer constituent material and a solvent, and for example, can be formed by an application method using an application liquid containing a conjugated polymer compound and fullerenes and/or derivatives of fullerenes and a solvent.

The solvent includes, for example, hydrocarbon solvents such as toluene, xylene, mesitylene, tetralin, decalin, bicyclohexyl, n-butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated hydrocarbon solvents such as chlorobenzene, dichlorobenzene, trichlorobenzene and the like, ether solvents such as tetrahydrofuran, tetrahydropyran and the like, etc.

The application liquid used in the present invention may contain two or more solvents, and may contain two or more of the above-exemplified solvents.

The method of applying an application liquid containing the above-described active layer constituent material includes application methods such as a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet printing method, a dispenser printing method, a nozzle coat method, a capillary coat method and the like, and of them, a spin coat method, a flexo printing method, an inkjet printing method and a dispenser printing method are preferable.

### <Sealing Layer Formation Step>

The sealing layer is provided by fixing a glass plate, a plastic plate, a polymer film and the like with a sealant composed of an UV hardening resin, a glass frit and the like onto an electrode opposite to an electrode in contact with a supporting substrate.

### <Toning Layer Formation Step>

The toning layer can be formed by directly applying or vacuum vapor-depositing a toning layer constituent material on a sealing layer or the surface of a supporting substrate, and can also be provided by pasting a toning layer composed of a glass plate or a colored semi-transparent film toned by applying a toning material and the like to a sealing layer or the surface of a supporting substrate with an adhesive or the like.

In the organic photoelectric conversion device of the present invention, when a transparent or semi-transparent electrode is irradiated with light such as solar light and the like, photovoltaic power is generated between electrodes, and the device can be operated as an organic film solar battery.

By integrating a plurality of organic film solar batteries, use as an organic film solar battery module is also made possible.

In the organic photoelectric conversion device of the present invention, when a transparent or semi-transparent electrode is irradiated with light under condition of application of voltage between electrodes, photocurrent flows, and the device can be operated as an organic optical sensor. By integrating a plurality of organic optical sensors, use as an organic image sensor is also made possible.

### EXAMPLES

Examples are shown below for illustrating the present invention further in detail, but the present invention is not limited to them

In the following examples, the polystyrene-equivalent number-average molecular weight and weight-average molecular weight were determined using GPC (PL-GPC2000) manufactured by GPC Laboratory CO. LTD., as the molecular weight of a polymer. A polymer was dissolved in o-dichlorobenzene so that the concentration of the polymer was about 1 wt %. o-dichlorobenzene was used as a mobile phase of GPC, and allowed to flow at a flow rate of 1 mL/min at a measurement temperature of 140° C. Three columns of PLGEL 10 μm MIXED-B (manufactured by PL Laboratory) were connected serially.

### Synthesis Example 1

### Synthesis of Compound 2

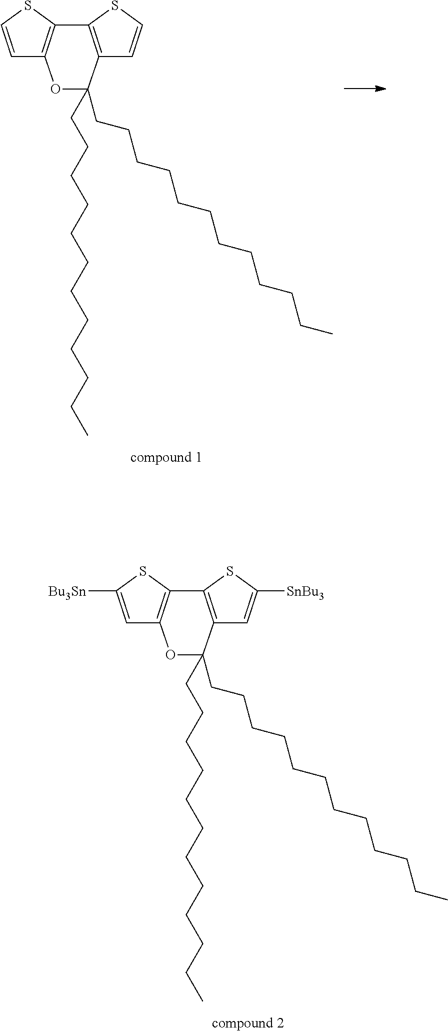

Into a 200 mL flask of which gas in the flask had been purged with argon were charged 2.00 g (3.77 mmol) of a compound 1 synthesized according to a description of International Publication WO2011/052709 and 100 mL of dehydrated tetrahydrofuran, and a uniform solution was prepared. While keeping the solution at −78° C., 5.89 mL (9.42 mmol) of a 1.6 M n-butyllithium hexane solution was dropped into the solution over a period of 10 minutes. After dropping, the reaction liquid was stirred at −78° C. for 30 minutes, then, stirred at room temperature (25° C.) for 2 hours. Thereafter, the flask was cooled down to −78° C., and 3.37 g (10.4 mmol) of tributyltin chloride was added to the reaction liquid. After addition, the reaction liquid was stirred at −78° C. for 30 minutes, then, stirred at room temperature (25° C.) for 3 hours. Thereafter, 200 ml of water was added to the reaction liquid to stop the reaction, and ethyl acetate was added and an organic layer containing the reaction product was extracted. The organic layer was dried over sodium sulfate, filtrated, then, the filtrate was concentrated by an evaporator, and the solvent was distilled off. The resultant oily substance was purified by a silica gel column using hexane as a developing solvent. As the silica gel for the silica gel column, silica gel which had been previously immersed in hexane containing 10 wt % trimethylamine for 5 minutes before rinsing with hexane was used. After purification, 3.55 g (3.20 mmol) of a compound 2 was obtained.

### Synthesis Example 2

### Synthesis of Polymer Compound 1

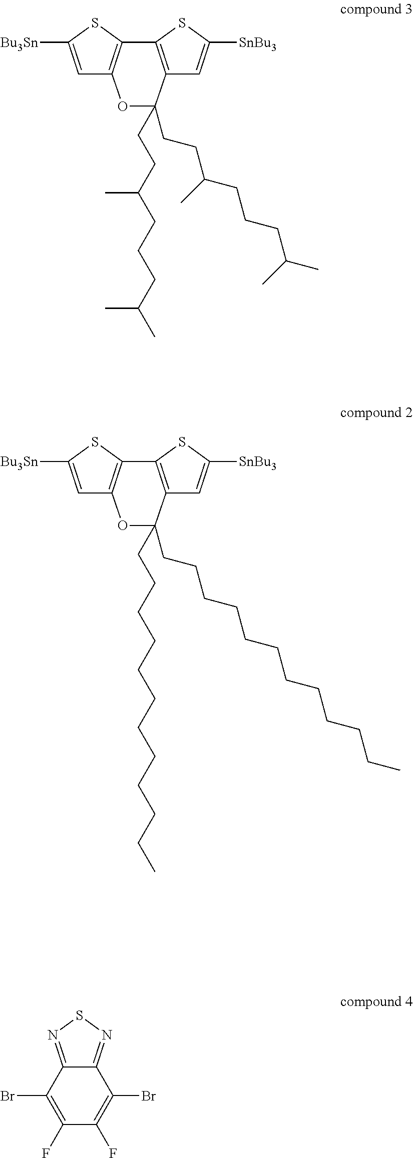

Into a 300 mL flask of which gas in the flask had been purged with argon were charged 800 mg (0.760 mmol) of a compound 3 synthesized according to a description of International Publication WO2011/052709, 840 mg (0.757 mmol) of the compound 2, 471 mg (1.43 mmol) of a compound 4 synthesized according to a description of International Publication WO2011/052709 and 107 ml of toluene, and a uniform solution was prepared. The resultant toluene solution was bubbled with argon for 30 minutes. Thereafter, to the toluene solution were added 19.6 mg (0.0214 mmol) of tris(dibenzylideneacetone)dipalladium and 39.1 mg (0.128 mmol) of tris(2-toluyl)phosphine, and the mixture was stirred at 100° C. for 6 hours. Thereafter, to the reaction liquid was added 660 mg of phenyl bromide, and the mixture was further stirred for 5 hours. Thereafter, the flask was cooled to 25° C., and the reaction liquid was poured into 2000 mL of methanol. The deposited polymer was collected by filtration, and the resultant polymer was placed in a cylindrical filter paper, and extracted with methanol, acetone and hexane each for 5 hours using a Soxhlet extractor. The polymer remaining in the cylindrical filter paper was dissolved in 53 mL of o-dichlorobenzene, and 1.21 g of sodium diethyldithiocarbamate and 12 mL of water were added, and the mixture was stirred for 8 hours under reflux. The aqueous layer was removed, then, the organic layer was washed with 200 ml of water twice, then, washed with 200 mL of a 3 wt % acetic acid aqueous solution twice, then, washed with 200 mL of water twice, and the resultant solution was poured into methanol to cause deposition of a polymer. The polymer was filtrated, then, dried, and the resultant polymer was again dissolved in 62 mL of o-dichlorobenzene, and the solution was allowed to pass through an alumina/silica gel column. The resultant solution was poured into methanol to cause deposition of a polymer, and the polymer was filtrated, then, dried, to obtain 802 mg of a purified polymer. Hereinafter, this polymer is called a polymer compound 1.

### Synthesis Example 3

### Synthesis of Polymer Compound 2

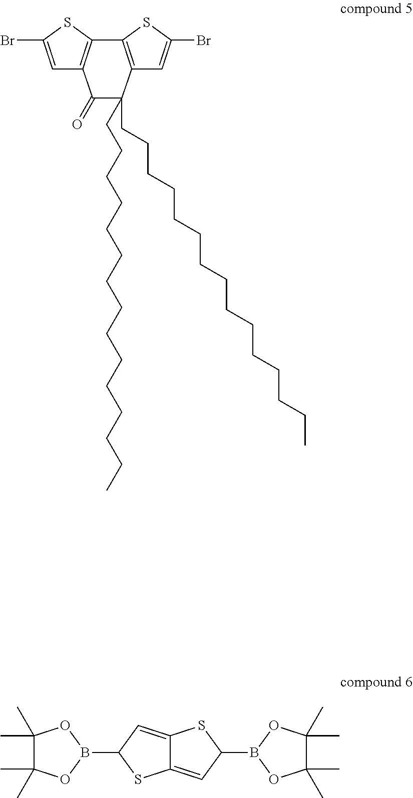

A nitrogen gas atmosphere was prepared in a 100 mL four-necked flask, then, a compound 5 (157 mg, 0.20 mmol) and dry THF (5 mL) were added, and the solution was deaerated by bubbling with an argon gas for 30 minutes. Thereafter, Pd₂(dba)₃ (9.16 mg, 1 μmol), tri-tert-butylphosphonium tetrafluoroborate (11.6 mg, 4 μmol) and a 3M potassium phosphate aqueous solution (1 mL) were added, and the mixture was stirred at 80° C. A dry THF (5 mL) solution of a compound 6 (78.4 mg, 0.20 mmol) deaerated by bubbling with an argon gas for 30 minutes at 80° C. was dropped into this reaction solution over a period of 5 minutes, and the mixture was stirred at 80° C. for 3 hours. A dry THF (7 mL) solution of phenylboronic acid (122 mg, 0.45 mmol) deaerated by bubbling with an argon gas for 30 minutes, Pd₂(dba)₃ (9.16 mg, 1 μmol) and tri-tert-butylphosphonium tetrafluoroborate (11.6 mg, 4 μmol) were added to this reaction solution at 80° C., and the mixture was stirred at 80° C. for 2 hours, sodium N,N-diethyldithiocarbamate trihydrate (1.7 g) and water (15 g) were added, and the mixture was further stirred at 80° C. for 2 hours. The aqueous layer in the resultant reaction solution was removed, then, the organic layer was washed with water (20 g) once, with a 10 wt % acetic acid aqueous solution (20 g) twice, with water (20 g) once, then, re-precipitation was caused using acetone (136 mL). The resultant solid was purified by column chromatography (SiO₂), and re-precipitation was caused using methanol, to obtain 120 mg of a polymer compound 2. The polymer compound C had a polystyrene-equivalent number-average molecular weight of 5.6×10⁴ and a polystyrene-equivalent weight-average molecular weight of 1.1×10⁵. The compound 5 can be synthesized by a method described in JP-A No. 2014-31364.

### Production of Composition 1

Ten (10) parts by weight of [6,6]-phenyl C61-butyric acid methyl ester (C60PCBM) (E100 manufactured by Frontier Carbon Corporation) as a derivative of fullerenes, 5 parts by weight of the polymer compound 1 as an electron donating compound and 1000 parts by weight of o-dichlorobenzene as a solvent were mixed. Next, the mixed solution was filtrated through a teflon (registered trademark) filter having a pore diameter of 5.0 μm, to prepare a composition 1.

### Production of Composition 2

Ten (10) parts by weight of [6,6]-phenyl C61-butyric acid methyl ester (C60PCBM) (E100 manufactured by Frontier Carbon Corporation) as a derivative of fullerenes, 5 parts by weight of the polymer compound 2 an electron donating compound and 1000 parts by weight of o-dichlorobenzene as a solvent were mixed. Next, the mixed solution was filtrated through a teflon (registered trademark) filter having a pore diameter of 5.0 μm, to prepare a composition 2.

### Example 1

### Fabrication and Evaluation of Organic Photoelectric Conversion Device

A glass substrate on which an ITO film functioning as an anode of a solar battery had been form was prepared. The ITO film was formed by a sputtering method, and its thickness was 150 nm. This glass substrate was treated with ozone and UV, thereby surface-treating the ITO film. Next, a PEDOT:PSS solution (manufactured by Heraeus, CleviosP VP AI4083) was applied on the ITO film by spin coating, and heated at 120° C. for 10 minutes in atmospheric air, to forma hole injection layer (corresponding to a hole transporting layer) having a thickness of 30 nm. On this hole injection layer, the above-described composition 1 was applied by spin coating, to form a first active layer (thickness: about 100 nm).

Next, a 45 wt % isopropanol dispersion liquid (HTD-711Z, manufactured by TAYCA) of zinc oxide nanoparticles (particle size: 20 nm to 30 nm) was diluted with 3-pentanol in an amount of 2.5-fold parts by weight of the dispersion liquid, to prepare an application liquid. This application liquid was applied on the active layer by spin coating with a film thickness of 200 nm, to form a functional layer which is insoluble in a water solvent. Thereafter, a neutral PEDOT:PSS dispersion liquid (manufactured by H. C. Starck, Clevios PN) of pH=6 to 7 was applied on the functional layer by spin coating with a film thickness of 30 nm.

Next, the above-described composition 2 was applied by spin coating, to form a second active layer (thickness: about 100 nm).

Next, a 45 wt % isopropanol dispersion liquid (HTD-711Z, manufactured by TAYCA) of zinc oxide nanoparticles (particle size: 20 nm to 30 nm) was diluted with 3-pentanol in an amount of 2.5-fold parts by weight of the dispersion liquid, to prepare an application liquid. This application liquid was applied on the active layer by spin coating with a film thickness of 200 nm, to form a functional layer which is insoluble in a water solvent.

Next, a wire-shaped conductor dispersion liquid using a water solvent (ClearOhm (registered trademark) Ink-N AQ: manufactured by Cambrios Technologies Corporation) was applied by a spin coater and dried, to obtain a cathode composed of an electrically conductive wire layer having a thickness of 120 nm. Thereafter, a semi-transparent organic photoelectric conversion device was obtained by fixing a glass plate on the cathode with an UV hardening sealant to form a sealing layer. This semi-transparent organic photoelectric conversion device showed gray transmission color, and the chromaticness C* in the L*C*h color system calculated from the transmittance spectrum was 5.5.

### Comparative Example 1

### Fabrication and Evaluation of Organic Photoelectric Conversion Device

A glass substrate on which an ITO film functioning as an anode of a solar battery had been form was prepared. The ITO film was formed by a sputtering method, and its thickness was 150 nm. This glass substrate was treated with ozone and UV, thereby surface-treating the ITO film. Next, a PEDOT:PSS solution (manufactured by Heraeus, CleviosP VP AI4083) was applied on the ITO film by spin coating, and heated at 120° C. for 10 minutes in atmospheric air, to forma hole injection layer having a thickness of 30 nm. On this hole injection layer, the above-described composition 1 was applied by spin coating, to form a first active layer (thickness: about 100 nm).

Next, a 45 wt % isopropanol dispersion liquid (HTD-711Z, manufactured by TAYCA) of zinc oxide nanoparticles (particle size: 20 nm to 30 nm) was diluted with 3-pentanol in an amount of 2.5-fold parts by weight of the dispersion liquid, to prepare an application liquid. This application liquid was applied on the active layer by spin coating with a film thickness of 200 nm, to form a functional layer which is insoluble in a water solvent.

Next, a wire-shaped conductor dispersion liquid using a water solvent (ClearOhm (registered trademark) Ink-N AQ: manufactured by Cambrios Technologies Corporation) was applied by a spin coater and dried, to obtain a cathode composed of an electrically conductive wire layer having a thickness of 120 nm. Thereafter, a semi-transparent organic photoelectric conversion device was obtained by fixing a glass plate on the cathode with an UV hardening sealant to form a sealing layer. This semi-transparent organic photoelectric conversion device showed green transmission color, and the chromaticness C* in the L*C*h color system calculated from the transmittance spectrum was 25.9.

### Comparative Example 2

### Fabrication and Evaluation of Organic Photoelectric Conversion Device

A glass substrate on which an ITO film functioning as an anode of a solar battery had been form was prepared. The ITO film was formed by a sputtering method, and its thickness was 150 nm. This glass substrate was treated with ozone and UV, thereby surface-treating the ITO film. Next, a PEDOT:PSS solution (manufactured by Heraeus, CleviosP VP AI4083) was applied on the ITO film by spin coating, and heated at 120° C. for 10 minutes in atmospheric air, to forma hole injection layer having a thickness of 30 nm. On this hole injection layer, the above-described composition 2 was applied by spin coating, to form a second active layer (thickness: about 100 nm).

Next, a 45 wt % isopropanol dispersion liquid (HTD-711Z, manufactured by TAYCA) of zinc oxide nanoparticles (particle size: 20 nm to 30 nm) was diluted with 3-pentanol in an amount of 2.5-fold parts by weight of the dispersion liquid, to prepare an application liquid. This application liquid was applied on the active layer by spin coating with a film thickness of 200 nm, to form a functional layer which is insoluble in a water solvent.

Next, a wire-shaped conductor dispersion liquid using a water solvent (ClearOhm (registered trademark) Ink-N AQ: manufactured by Cambrios Technologies Corporation) was applied by a spin coater and dried, to obtain a cathode composed of an electrically conductive wire layer having a thickness of 120 nm. Thereafter, a semi-transparent organic photoelectric conversion device was obtained by fixing a glass plate on the cathode with an UV hardening sealant to form a sealing layer. This semi-transparent organic photoelectric conversion device showed purple transmission color, and the chromaticness C* in the L*C*h color system calculated from the transmittance spectrum was 13.0.

### Example 2

### Fabrication and Evaluation of Organic Photoelectric Conversion Device

The organic photoelectric conversion device obtained in Comparative Example 1 and the organic photoelectric conversion device obtained in Comparative Example 2 were superimposed and serially connected with conductive wires, to fabricate a semi-transparent organic photoelectric conversion device. This semi-transparent organic photoelectric conversion device showed gray color, and the chromaticness C* in the L*C*h color system calculated from the transmittance spectrum was 9.4.

### Example 3

### Fabrication and Evaluation of Organic Photoelectric Conversion Device

The organic photoelectric conversion device obtained in Comparative Example 1 and the organic photoelectric conversion device obtained in Comparative Example 2 were superimposed and parallely connected with conductive wires, to fabricate a semi-transparent organic photoelectric conversion device. This semi-transparent organic photoelectric conversion device showed gray color, and the chromaticness C* in the L*C*h color system calculated from the transmittance spectrum was 9.4.

A 1 cm×1 cm regular tetragonal shield mask was covered on these semi-transparent organic photoelectric conversion devices to prescribe the light-receiving area, and the resultant organic photoelectric conversion devices were irradiated with constant light using Solar Simulator (manufactured by Bunkoukeiki Co., Ltd., trade name: OTENTO-SUNII: AM 1.5G filter, irradiance: 100 mW/cm²) and generating current and voltage were measured, thus, the photoelectric conversion efficiency was measured. The results obtained are shown in Table 1.

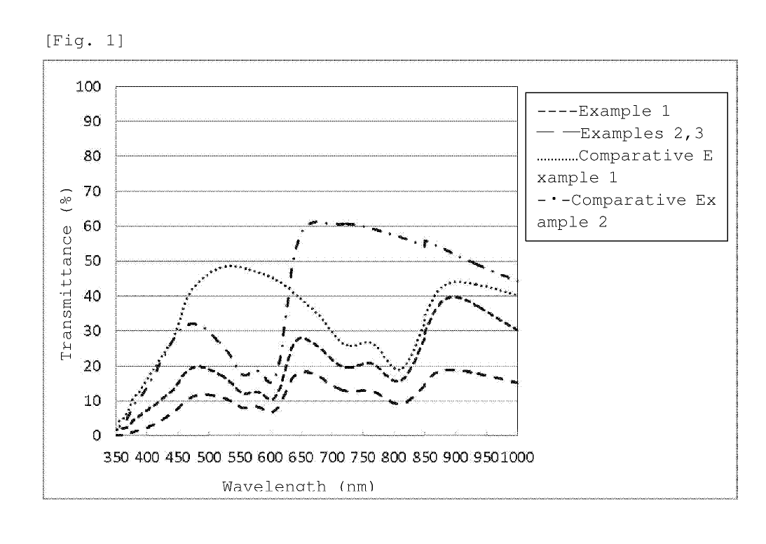

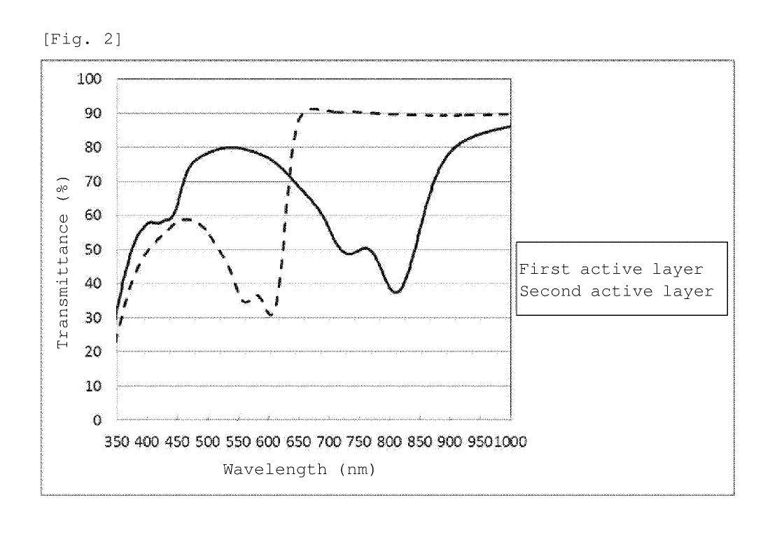

The transmittance spectra of these semi-transparent organic photoelectric conversion devices were measured by a spectrophotometer (manufactured by JASCO Corporation, trade name: V-670). The transmittance spectra of the organic photoelectric conversion devices fabricated in Examples 1, 2 and 3 and Comparative Examples 1 and 2 are shown in FIG. 1. The transmittance spectra of the first active layer only and the second active layer only used in Examples 1, 3 and 4 and Comparative Examples 1 and 2 are shown in FIG. 2. From the transmittance spectra in the range of 380 nm to 780 nm, the L*a*b* chromaticity coordinate, the chromaticness C* and the hue h were calculated, and the results obtained are shown in Table 2. The hue h in the L*C*h color system calculated from the transmittance spectrum of the first active layer was 103.7°, and the hue h in the L*C*h color system calculated from the transmittance spectrum of the second active layer was 333.5°.

TABLE 1

| | | Short-circuit | | |
|---|---|---|---|---|
| | | current | Open end | |
| | Efficiency | density | voltage | |
| | (%) | (mA/cm2) | (V) | FF |
| Example 1 | 4.75 | 5.57 | 1.44 | 0.59 |
| Example 2 | 4.09 | 5.46 | 1.54 | 0.49 |
| Example 3 | 4.47 | 10.6 | 0.72 | 0.59 |
| Comparative | 3.13 | 8.14 | 0.68 | 0.57 |
| Example 1 | | | | |
| Comparative | 3.06 | 6.00 | 0.89 | 0.57 |
| Example 2 | | | | |

TABLE 2

| | L | a* | b* | C* | h |
|---|---|---|---|---|---|
| Example 1 | 46.7 | 2.9 | 4.6 | 5.5 | 57.7° |
| Example 2 | 38.1 | 1.0 | 9.4 | 9.4 | 83.9° |
| Example 3 | ″ | ″ | ″ | ″ | ″ |
| Comparative | 75.8 | −8.5 | 24.5 | 25.9 | 109.1° |
| Example 1 | | | | | |
| Comparative | 56.7 | 12.9 | −1.30 | 13.0 | 354.3° |
| Example 2 | | | | | |
| First active | 93.0 | −4.7 | 19.3 | 19.9 | 103.7 |
| layer | | | | | |
| Second active | 73.6 | 11.5 | −5.7 | 12.8 | 333.5 |
| layer | | | | | |

As described above, the organic photoelectric conversion devices of Examples 1, 2 and 3 obtained by superimposing green and purple active layers which are in a relation of mutually complementary colors have a chromaticness C* in the L*C*h color system of as small as 12 or less, show gray transmission color, thus, are suitable for window application.

### INDUSTRIAL APPLICABILITY

According to the present invention, a photoelectric conversion device having low chromaticness is provided.

1. A photoelectric conversion device comprising a layer A having a hue value of h₁ in the L*C*h color system calculated from the transmittance spectrum and a layer B having a hue value of h₂ in the L*C*h color system calculated from the transmittance spectrum, wherein h₁ and h₂ satisfy h₁+100≦h₂≦h₁+260.

2. The photoelectric conversion device according to claim 1, wherein the device is an organic photoelectric conversion device.

3. The photoelectric conversion device according to claim 1, wherein the chromaticness C* in the L*C*h color system calculated from the transmittance spectrum is 12 or less.

4. The photoelectric conversion device according to claim 1, wherein at least one of the layer A and the layer B is a semiconductor layer.

5. The photoelectric conversion device according to claim 4, wherein both the layer A and the layer B are semiconductor layers.

6. The photoelectric conversion device according to claim 4, wherein the semiconductor layer is an active layer.

7. The photoelectric conversion device according to claim 1, wherein either the layer A or the layer B is a toning layer.

8. The photoelectric conversion device according to claim 1, wherein at least one of the layer A and the layer B has a chromaticness C* of 12 or more in the L*C*h color system calculated from the transmittance spectrum of the each layer only.

9. The photoelectric conversion device according to claim 1, wherein both the layer A and the layer B have a chromaticness C* of 12 or more in the L*C*h color system calculated from the transmittance spectrum of the each layer only.
